(19) United States
(12) Patent Application Publication
(10) Pub. No.: US 2025/0338537 A1
(43) Pub. Date: Oct. 30, 2025

(54) SEMICONDUCTOR DEVICE

(71) Applicant: SAMSUNG ELECTRONICS CO., LTD., SUWON-SI (KR)

(72) Inventors: JOONYONG KIM, Suwon-si (KR); IN JUN HWANG, Suwon-si (KR)

(21) Appl. No.: 18/966,384

(22) Filed: Dec. 3, 2024

(30) Foreign Application Priority Data
Apr. 30, 2024 (KR) 10-2024-0058027

(51) Int. Cl. H10D 30/47; H10D 62/85; H10D 64/27; H10D 89/60

(52) U.S. Cl. CPC H10D 30/475; H10D 62/8503; H10D 64/411; H10D 89/60

(57) ABSTRACT

A semiconductor device includes: a high electron mobility transistor; a resisting element; an inverter circuit connected to the resisting element; and a first transistor, wherein the high electron mobility transistor includes: a channel layer; a barrier layer disposed on the channel layer and including a material having a different energy band gap from that of the channel layer; a gate electrode disposed on the barrier layer; a gate semiconductor layer disposed between the barrier layer and the gate electrode; and a main source electrode and a main drain electrode respectively disposed on opposite sides of the gate electrode and connected to the channel layer, wherein the resisting element is connected between the gate electrode and the main source electrode, and wherein the first transistor includes a gate that is connected between the main source electrode and the gate electrode and connected to the inverter circuit.

### CROSS-REFERENCE TO RELATED APPLICATION

This application claims priority under 35 U.S.C. § 119 to Korean Patent Application No. 10-2024-0058027 filed in the Korean Intellectual Property Office on Apr. 30, 2024, the disclosures of which are incorporated by reference herein in their entireties.

### TECHNICAL FIELD

The present inventive concept relates to a semiconductor device.

### DISCUSSION OF THE RELATED ART

In the modern society, semiconductor devices are frequently used is daily life. For example, the importance of power semiconductor devices used in various fields such as transportation fields including, for example, electric vehicles, railways, and electric trams, renewable energy systems such as solar power generation and wind power generation, and mobile devices is gradually increasing. The power semiconductor device is used to control high voltages or high currents, and performs functions such as electric power conversion and control in large electric power systems or high-power electronic devices. The power semiconductor devices have the ability and durability to process high electric power, process large amounts of current, and withstand high voltages. For example, the power semiconductor device may process voltages of hundreds to thousands of volts and currents of tens to thousands of amperes. The power semiconductor devices may increase the efficiency of electrical energy by minimizing power loss. The power semiconductor devices may be stably operated in environments such as high temperatures.

These semiconductor devices may be classified according to materials, and for example, they may include a SiC power semiconductor device and a GaN electric power semiconductor device. By manufacturing the power semiconductor devices using SiC or GaN instead of existing silicon wafers (Si wafers), the drawbacks of silicon, which include unstable characteristics at relatively high temperatures, may be compensated. The GaN power semiconductor devices may have high costs, but are efficient in terms of speed and may be suitable for high-rate charging of mobile devices.

### SUMMARY

According to an embodiment of the present inventive concept, a semiconductor device includes: a high electron mobility transistor; a resisting element; an inverter circuit connected to the resisting element; and a first transistor, wherein the high electron mobility transistor includes: a channel layer; a barrier layer disposed on the channel layer and including a material having a different energy band gap from that of the channel layer; a gate electrode disposed on the barrier layer; a gate semiconductor layer disposed between the barrier layer and the gate electrode; and a main source electrode and a main drain electrode respectively disposed on opposite sides of the gate electrode and connected to the channel layer, wherein the resisting element is connected between the gate electrode and the main source electrode, and wherein the first transistor includes a gate that is connected between the main source electrode and the gate electrode and connected to the inverter circuit.

According to an embodiment of the present inventive concept, a semiconductor device includes: a high electron mobility transistor; a resisting element; and a first transistor, wherein the high electron mobility transistor includes: a channel layer; a barrier layer disposed on the channel layer; a gate electrode disposed on the barrier layer; a gate semiconductor layer disposed between the barrier layer and the gate electrode; and a main source electrode and a main drain electrode respectively disposed on opposite sides of the gate electrode and connected to the channel layer; the resisting element includes: a first channel pattern including a drift resistance region having two-dimensional electron gas; a sub-source electrode disposed on the first channel pattern and connected to the main source electrode; a first connection wire disposed on the first channel pattern and connected to the gate electrode; and a second connection wire disposed between the sub-source electrode and the first connection wire and disposed on the first channel pattern, and the first transistor includes: a second channel pattern connected to the sub-source electrode and the first connection wire; a first gate electrode disposed between the sub-source electrode and the first connection wire and disposed on the second channel pattern; and a first gate semiconductor layer disposed between the first gate electrode and the second channel pattern.

According to an embodiment of the present inventive concept, a semiconductor device includes: a high electron mobility transistor; a resisting element; a first transistor; and an inverter circuit, wherein the high electron mobility transistor includes: a channel layer; a barrier layer disposed on the channel layer; a gate electrode disposed on the barrier layer; a gate semiconductor layer disposed between the barrier layer and the gate electrode; and a main source electrode and a main drain electrode respectively disposed on opposite sides of the gate electrode and connected to the channel layer, the resisting element includes: a first channel pattern disposed on one side of the channel layer; a sub-source electrode disposed on the first channel pattern and connected to the main source electrode; a first connection wire disposed on the first channel pattern and connected to the gate electrode; and a second connection wire disposed between the sub-source electrode and the first connection wire and disposed on the first channel pattern, the first transistor includes: a second channel pattern disposed between the first channel pattern and the channel layer and connected to the sub-source electrode and the first connection wire; a first gate electrode disposed between the sub-source electrode and the first connection wire and disposed on the second channel pattern; and a first gate semiconductor layer disposed between the first gate electrode and the second channel pattern, and the inverter circuit includes: a third channel pattern disposed between the first channel pattern and the second channel pattern and connected to the sub-source electrode; a third connection wire disposed on the third channel pattern and connected to the first gate electrode; a second gate electrode disposed on the third channel pattern and connected to the second connection wire; and a second gate semiconductor layer disposed between the third channel pattern and the second gate electrode.

### BRIEF DESCRIPTION OF THE DRAWINGS

FIG. 1 shows a block diagram of an electric power system according to an embodiment of the present inventive concept.

FIG. 2 shows a block diagram on an electric power system according to an embodiment of the present inventive concept.

FIG. 3 shows a block diagram on a semiconductor device according to an embodiment of the present inventive concept.

FIG. 4 shows a circuit diagram on a semiconductor device according to an embodiment of the present inventive concept.

FIG. 5 shows a circuit diagram on a digitizer circuit according to an embodiment of the present inventive concept.

FIG. 6 shows a top plan view on a semiconductor device according to an embodiment of the present inventive concept.

FIG. 7 and FIG. 8 show cross-sectional views with respect to a line A-A′ of FIG. 6.

FIG. 9 shows a cross-sectional view with respect to a line B-B′ of FIG. 6.

FIG. 10 shows a cross-sectional view with respect to a line C-C′ of FIG. 6.

FIG. 11 shows a cross-sectional view with respect to a line D-D′ of FIG. 6.

FIG. 12 shows a cross-sectional view with respect to a line E-E′ of FIG. 6.

FIG. 13 shows a cross-sectional view on a semiconductor device according to embodiments of the present inventive concept, corresponding to C-C′ of FIG. 6.

FIG. 14 shows a top plan view on a semiconductor device according to embodiments of the present inventive concept.

FIG. 15 shows a cross-sectional view with respect to a line F-F′ of FIG. 14.

FIG. 16 shows a cross-sectional view with respect to a line G-G′ of FIG. 14.

FIG. 17 shows a circuit diagram on a semiconductor device according to embodiments of the present inventive concept.

FIG. 18 shows a top plan view on a semiconductor device according to an embodiment of FIG. 17.

FIG. 19 shows a cross-sectional view with respect to a line H-H′ of FIG. 18.

FIG. 20 and FIG. 21 show cross-sectional views on a semiconductor device according to embodiments of the present inventive concept, corresponding to H-H′ of FIG. 18.

FIG. 22 shows a circuit diagram on a semiconductor device according to embodiments of the present inventive concept.

FIG. 23 shows a top plan view on a semiconductor device according to an embodiment of FIG. 22.

FIG. 24 shows a cross-sectional view with respect to a line I-I′ of FIG. 23.

FIG. 25 shows a cross-sectional view on a semiconductor device according to embodiments of the present inventive concept, corresponding to I-I′ of FIG. 23.

### DETAILED DESCRIPTION OF THE EMBODIMENTS

The present inventive concept will be described more fully hereinafter with reference to the accompanying drawings. As those skilled in the art would realize, the described embodiments may be modified in various different ways, all without departing from the spirit or scope of the present inventive concept.

The same elements will be designated by the same reference numerals throughout the specification and drawings.

In the drawings, various thicknesses, lengths, and angles are shown and

while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be understood that when an element such as a layer, film, region, or substrate is referred to as being “on” another element, it can be directly on the other element or intervening elements may also be present.

The phrase “in a plan view” means viewing an object portion from the top, and the phrase “in a cross-sectional view” means viewing a cross-section of which the object portion is vertically cut from the side.

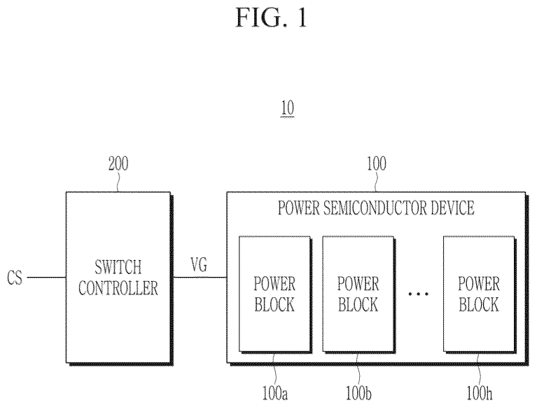

FIG. 1 shows a block diagram of an electric power system according to an embodiment of the present inventive concept.

Referring to FIG. 1, the electric power system 10 may use electric power and may include, for example, transportation fields including, for example, electric vehicles, railways, or electric trams, renewable energy systems such as solar power generation or wind power generation, mobile devices, home appliances, etc. The electric power system 10 may supply electric power to a load from an electric power source. The electric power system 10 may supply electric power to the load or may perform an electric power conversion according to switching by a switching element. The electric power system 10 may include at least one or more components for converting, controlling or distributing electric power. As an example, the electric power system 10 may include an inverter, a converter, a power management IC (PMIC), and/or a power distribution unit (PDU). Components included in the electric power system 10 (e.g., inverter, converter, PMIC, and PDU) may include various discrete semiconductor devices to perform the function of converting, controlling, or distributing electric power. For example, the electric power system 10 may include discrete semiconductor devices including transistors such as IGBT or MOSFET, diodes, or thyristors.

In embodiments of the present inventive concept, the electric power system 10 may include semiconductor devices for performing switching operations. In other words, the electric power system 10 may control or convert supplied electric power by controlling the on/off operation of the semiconductor devices.

The electric power system 10 according to an embodiment of the present inventive concept may include a switch controller 200 and a semiconductor device 100.

The switch controller 200 may control the semiconductor device 100. In an embodiment of the present inventive concept, the switch controller 200 may receive a control signal CS and may output a gate signal VG based on the control signal CS. The control signal CS can be input from an inside or outside of the electric power system 10. For example, the control signal CS may be output from microprocessors such as a central processing unit (CPU) chip, a graphic processing unit (GPU) chip, or an application processor (AP) chip. The control signal CS may be output from an integrated circuit (IC) included in the electric power system 10. The switch controller 200 may generate a gate signal VG with a target size or waveform based on information that is included in the control signal CS and may output it to the outside.

The gate signal VG may control the discrete semiconductor devices included in the semiconductor device 100. For example, the gate signal VG may be an electric signal supplied to the terminal of the discrete semiconductor device included in the semiconductor device 100. In embodiments of the present inventive concept, the gate signal VG may have a value that is greater than that of the control signal CS, but is not limited thereto. For example, when the gate signal VG and the control signal CS are voltage signals, a voltage range of the gate signal VG may be greater than the voltage range of the control signal CS. The switch controller 200 may convert electrical signals that are received from the outside into appropriate signals for controlling the discrete semiconductor devices that are included in the semiconductor device 100, and may provide the converted signals to the semiconductor device 100. In an embodiment of the present inventive concept, the switch controller 200 may operate as a signal amplifier for processing fast on/off switching of the discrete semiconductor devices included in the semiconductor device 100.

The semiconductor device 100 may include power blocks 100a, 100b, . . . , 100h. The power blocks 100a, 100b, . . . , 100h may be discrete semiconductor devices for performing one unit function, or a set of discrete semiconductor devices and/or passive elements that are configured to perform the one unit function. The one unit function may be, for example, a switching operation or a rectification operation. However, the function performed by the respective power blocks 100a, 100b, . . . , 100h might not be limited to the switching and rectification operations. For example, the respective power blocks 100a, 100b, . . . , 100h may be designed to perform not only the switching operation and the rectification operation, but also various operations performed by various known discrete semiconductor devices. The power blocks 100a, 100b, . . . , 100h may be included in the semiconductor device 100, and together with the other power blocks 100a, 100b, . . . , 100h in the semiconductor device 100, they may convert and control the electric power like the inverter, the converter, the PMIC, etc.

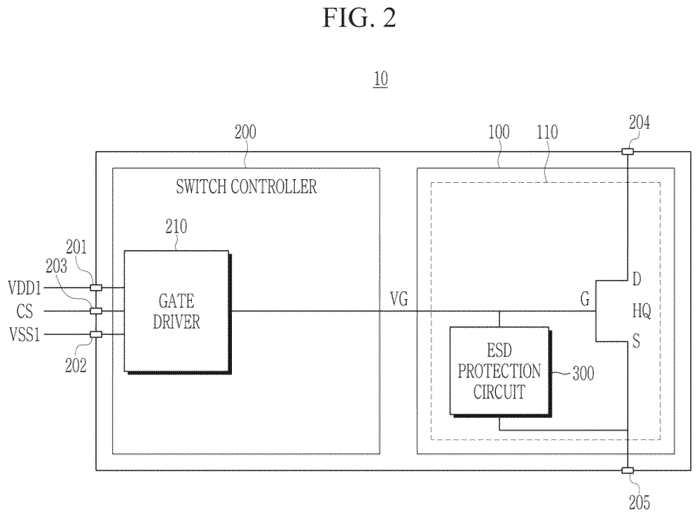

FIG. 2 shows a block diagram on an electric power system according to an embodiment of the present inventive concept.

Referring to FIG. 2, the electric power system 10 may include terminals 201, 202, and 203 for receiving signals that are provided to the switch controller 200, and load terminals 204 and 205 corresponding to a drain D and a source S of the high electron mobility transistor HQ.

The switch controller 200 may be connected to the semiconductor device 100. The switch controller 200 may be connected to the terminals 201, 202, and 203, and the semiconductor device 100 may be connected to the load terminals 204 and 205. For better understanding and ease of description, see FIG. In 2, the semiconductor device 100 including one power block is shown, but one switch controller 200 may be connected to the semiconductor device 100 including power blocks. For better understanding and ease of description, FIG. 2 shows the semiconductor device 100 including a power block, and one switch controller 200 may be connected to the semiconductor device 100 including power blocks.

The switch controller 200 may receive a first driving voltage VDD1, a second driving voltage VSS1, and a control signal CS, and may output a gate signal VG based on the first driving voltage VDD1, the second driving voltage VSS1, and the control signal CS. The switch controller 200 may include a gate driver 210. In embodiments of the present inventive concept, the switch controller 200 may further include a level shifter for level shifting the signal received from the gate driver 210.

The gate driver 210 may generate a gate signal VG based on the control signal CS that is received from the outside (e.g., an external device). The gate driver 210 may then provide the gate signal VG to the semiconductor device 100.

The semiconductor device 100 may include a substrate 110 on which the high electron mobility transistor HQ is disposed. In embodiments of the present inventive concept, the substrate 110 may be a die of GaN. FIG. 2 shows that the switch controller 200 is not disposed on the substrate 110. In an embodiment of the present inventive concept, some components in the switch controller 200 may be disposed on the substrate 110, but the present inventive concept is not limited thereto.

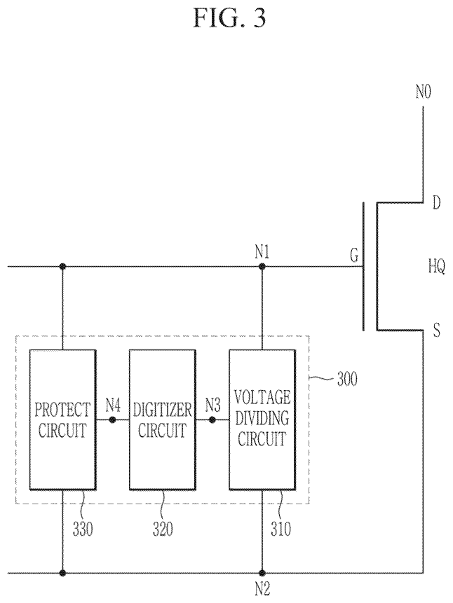

The semiconductor device 100 may include a high electron mobility transistor HQ and an electrostatic discharge protection circuit 300. The high electron mobility transistor HQ may be a switching element that is included in one of the power blocks 100a, 100b, . . . , 100h described with reference to FIG. 1. The high electron mobility transistor HQ may be connected between the load terminals 204 and 205. For example, the drain D of the high electron mobility transistor HQ may be connected to the load terminal 204, and the source S of the high electron mobility transistor HQ may be connected to the load terminal 205. Unlike what is shown in FIG. 3, other active elements and/or passive elements may be disposed between the drain D of the high electron mobility transistor HQ and the load terminal 204, and/or between the source S of the high electron mobility transistor HQ and the load terminal 205.

In embodiments of the present inventive concept, a power voltage may be supplied to the load terminal 204 from a voltage source. For example, the power voltage may have a voltage level of about 40V to about 1000V. The load terminal 205 may have a lower voltage level than the power voltage. For example, the load terminal 205 may be grounded. However, the present inventive concept is not limited to this, and a voltage having a negative voltage level or having a positive voltage level that is lower than that of the load terminal 204 may be supplied to the load terminal 205.

A gate G of the high electron mobility transistor HQ may be connected to an output end of the switch controller 200. The high electron mobility transistor HQ may receive a gate signal VG from the output end of the switch controller 200. The high electron mobility transistor HQ may be turned on or turned off based on the level of the gate signal VG that is provided from the switch controller 200. For example, when a potential difference between the gate signal VG and the drain D of the high electron mobility transistor HQ has a level that is equal to or greater than a threshold voltage of the high electron mobility transistor HQ, the high electron mobility transistor HQ may be turned on. For example, when the potential difference between the gate signal VG and the drain D of the high electron mobility transistor HQ has a level that is lower than the threshold voltage of the high electron mobility transistor HQ, the high electron mobility transistor HQ may be turned off.

The electrostatic discharge protection circuit 300 may prevent damage to the high electron mobility transistor HQ and the electric power system 10 including the high electron mobility transistor HQ when an electrostatic discharge (ESD) is generated in the electric power system 10. An electrostatic discharge (ESD) through which the voltage momentarily applied to the high electron mobility transistor HQ increases may be generated by strokes of lightning generated around the electric power system 10 or the operation of another system using much electric power.

The electrostatic discharge protection circuit 300 may control the size of the gate signal VG of the high electron mobility transistor HQ when the electrostatic discharge (ESD) occurs. In an embodiment of the present inventive concept, the electrostatic discharge protection circuit 300 may connect a protective circuit between the gate G and the source S of the high electron mobility transistor HQ during the electrostatic discharge (ESD). The electrostatic discharge protection circuit 300 may disconnect the protective circuit between the gate G and the source S of the high electron mobility transistor HQ during a normal operation in which the electrostatic discharge (ESD) does not occur.

For example, the electrostatic discharge protection circuit 300 may be operated based on the voltage between the gate G and source S of the high electron mobility transistor HQ. For example, the electrostatic discharge protection circuit 300 may connect the protective circuit between the gate G and the source S when the voltage between the gate G and the source S exceeds a predetermined threshold value. The electrostatic discharge protection circuit 300 may disconnect the protective circuit between the gate G and the source S when the voltage between the gate G and the source S is below a predetermined threshold value.

The electrostatic discharge protection circuit 300 may be operated based on a voltage that is obtained by dividing the voltage between the gate G and the source S. For example, the electrostatic discharge protection circuit 300 may connect the protective circuit between the gate G and the source S when the voltage that is obtained by dividing the voltage between the gate G and the source S exceeds a predetermined threshold value. The electrostatic discharge protection circuit 300 may disconnect the protective circuit between the gate G and the source S when the voltage obtained by dividing the voltage between the gate G and the source S is less than a predetermined threshold value.

In an embodiment of the present inventive concept, the electrostatic discharge protection circuit 300 may be provided by the number of the high electron mobility transistors HQ included in the electric power system 10. For example, the electric power system 10 may include high electron mobility transistors HQ, and electrostatic discharge protection circuits 300 connected between the gate G and the source S of the respective high electron mobility transistors HQ. However, without being limited thereto, the electric power system 10 may have one electrostatic discharge protection circuit 300 per power block. For example, the power blocks 100a, 100b, . . . , 100h described with reference to FIG. 1 may respectively include high electron mobility transistors HQ, and the high electron mobility transistors HQ may be connected in common with one electrostatic discharge protection circuit 300.

In an embodiment of the present inventive concept, the semiconductor device 100 may further include various elements that are connected to the high electron mobility transistor HQ and perform additional operations. For example, the semiconductor device 100 may further include passive elements such as a capacitor or an inductor, or active elements such as an integrated circuit (IC) chip. For another example, the semiconductor device 100 may further include a current divider, a voltage divider, a voltage clipper, and a protection element for the high electron mobility transistor HQ. For another example, the semiconductor device 100 may further include elements for protecting the high electron mobility transistor HQ such as an overcurrent protection device, an overvoltage protection device, an over-temperature protection device, a short-circuit protection device, a low drop-output (LDO) regulator, etc.

FIG. 3 shows a block diagram on a semiconductor device according to an embodiment of the present inventive concept.

Referring to FIG. 3, the drain D of the high electron mobility transistor HQ may be connected to an O-node NO. In addition, the gate G may be connected to a first node N1, and the source S may be connected to a second node N2. The electrostatic discharge protection circuit 300 may be connected between the gate G and the source S of the high electron mobility transistor HQ. The electrostatic discharge protection circuit 300 may be connected between the first node N1 and the second node N2. The electrostatic discharge protection circuit 300 may include a voltage dividing circuit 310, a digitizer circuit 320, and a protective circuit 330.

The voltage dividing circuit 310 may divide the voltage of the gate signal VG of the high electron mobility transistor HQ and may output the divided voltage to the digitizer circuit 320. The voltage dividing circuit 310 may be connected between the first node N1 and the second node N2, and may output the divided voltage to the third node N3.

The digitizer circuit 320 may be connected to the voltage dividing circuit 310 at the third node N3, and may be connected to the protective circuit 330 at a fourth node N4. The digitizer circuit 320 may receive the voltage that is divided by the voltage dividing circuit 310 at the third node N3, and may output a first voltage or a second voltage that is lower than the first voltage based on the divided voltage. In an embodiment of the present inventive concept, the digitizer circuit 320 may output the first voltage when the divided voltage is higher than the threshold voltage, and it may output the second voltage when the divided voltage is equal to or lower than the threshold voltage.

The protective circuit 330 may be connected between the gate G and the source S of the high electron mobility transistor HQ between the first node N1 and the second node N2, and may be connected to the digitizer circuit 320 at the fourth node N4. The protective circuit 330 may connect or disconnect the first node N1 and the second node N2 based on the voltage output by the digitizer circuit 320. When the protective circuit 330 connects the first node N1 and the second node N2, the first node N1 and the second node N2 may be short-circuited.

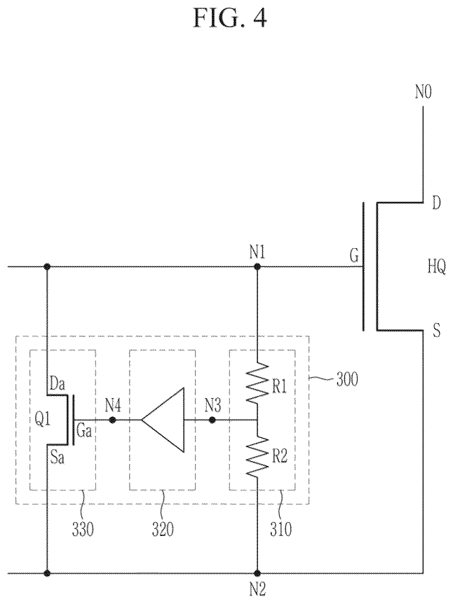

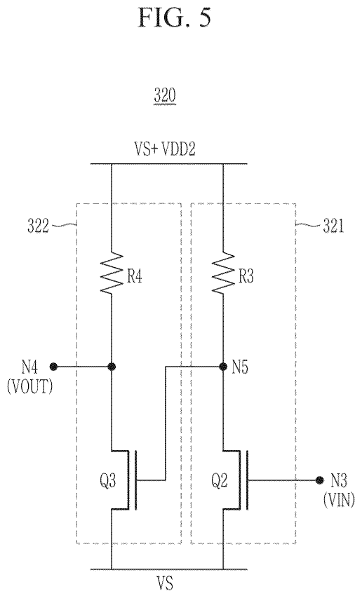

A semiconductor device according to an embodiment of the present inventive concept will now be described with reference to FIG. 4 and FIG. 5.

FIG. 4 shows a circuit diagram on a semiconductor device according to an embodiment of the present inventive concept. FIG. 5 shows a circuit diagram on a digitizer circuit according to an embodiment of the present inventive concept.

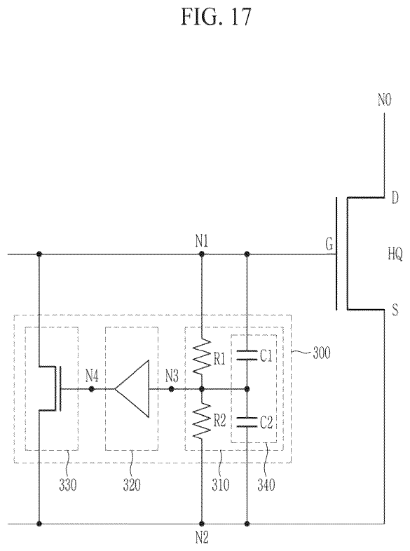

Referring to FIG. 4, the voltage dividing circuit 310 of the semiconductor device according to an embodiment of the present inventive concept may include resistors R1 and R2 coupled in series between the first node N1 and the second node N2. The voltage divided according to resistance ratio of the resistors R1 and R2 may be output to the third node N3. In embodiments of the present inventive concept, the voltage dividing circuit 310 may further include capacitors that are coupled in series between the first node N1 and the second node N2. This will be described later with reference to FIG. 17. For another example, the voltage dividing circuit 310 may only include capacitors that are coupled in series between the first node N1 and the second node N2.

The digitizer circuit 320 may be electrically connected between the third node N3 and the fourth node N4. The digitizer circuit 320 may output the first voltage or the second voltage to the fourth node N4 depending on the voltage size that is input from the third node N3.

Referring to FIG. 5, the digitizer circuit 320 may include inverter circuits 321 and 322 coupled in series between the third node N3 and the fourth node N4.

The first inverter circuit 321 may include a second transistor Q2 that is connected between a fifth node N5 and the second voltage VS and that includes a gate connected to the third node N3. The first inverter circuit 321 further includes a third resistor R3 that is connected between the first voltage (VS+VDD2) and the fifth node N5. The third node N3 may be an input end of the first inverter circuit 321, and the fifth node N5 may be an output end of the first inverter circuit 321.

The second inverter circuit 322 may include a third transistor Q3 that is connected between the fourth node N4 and the second voltage VS and that includes a gate connected to the fifth node N5. The second inverter circuit 322 further includes a fourth resistor R4 that is connected between the first voltage (VS+VDD2) and the fourth node N4. The fifth node N5 may be an input end of the second inverter circuit 322, and the fourth node N4 may be an output end of the second inverter circuit 322.

Referring to FIG. 4, the protective circuit 330 may include a first transistor Q1, which is connected between the first node N1 and the second node N2 and which includes a gate connected to the fourth node N4. A drain Da of the first transistor Q1 may be connected to the first node N1, and a source Sa of the first transistor Q1 may be connected to the second node N2. A gate Ga of the first transistor Q1 may be connected to an output end of the digitizer circuit 320 through the fourth node N4.

In an embodiment of the present inventive concept, the first transistor Q1 may receive a gate signal from the output end (e.g., fourth node N4) of the digitizer circuit 320. The first transistor Q1 may be turned on or turned off based on the level of the gate signal that is provided from the digitizer circuit 320. For example, the gate Ga of the first transistor Q1 may receive a first voltage or a second voltage that is lower than the first voltage from the digitizer circuit 320. The first voltage may be equal to or greater than the threshold voltage of the first transistor Q1. The second voltage may be less than the threshold voltage of the first transistor Q1. Accordingly, when the first voltage is applied to the gate Ga of the first transistor Q1, first transistor Q1 may be turned on, allowing a short-circuit between the first node N1 and the second node N2. When the second voltage is applied to the gate Ga of the first transistor Q1, the first transistor Q1 may be turned off.

In an embodiment of the present inventive concept, when electrostatic discharge (ESD) occurs, a high voltage may be momentarily applied to the first node N1 that is connected to the gate G of the high electron mobility transistor HQ. The voltage dividing circuit 310 may divide the voltage that is applied to the first node N1 and may output the divided voltage to the digitizer circuit 320, and the digitizer circuit 320 may output the first voltage to the gate Ga of the first transistor Q1. Accordingly, the first transistor Q1 may be turned on, and the voltage at the first node N1 may be reduced to protect the gate G of the high electron mobility transistor HQ from a high voltage.

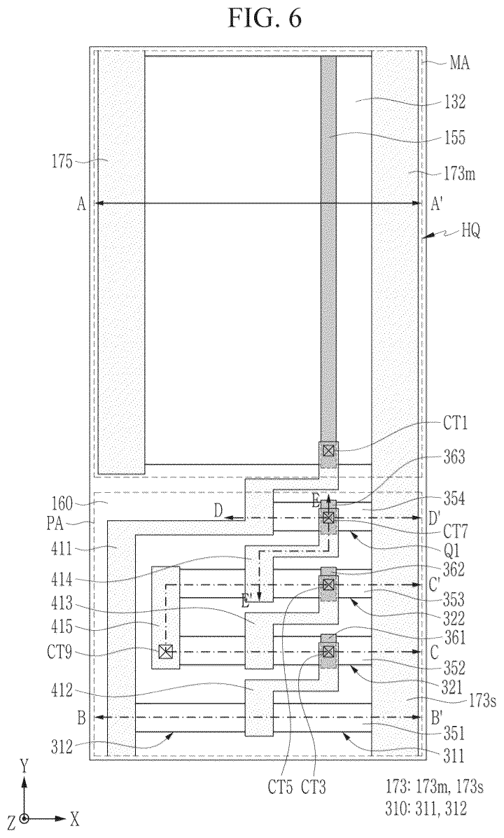

The high electron mobility transistor of the semiconductor device according to an embodiment of the present inventive concept will now be described with reference to FIG. 6 to FIG. 8.

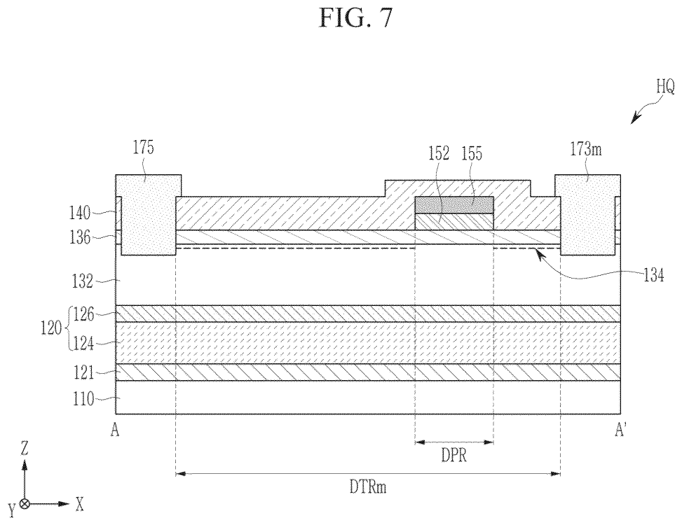

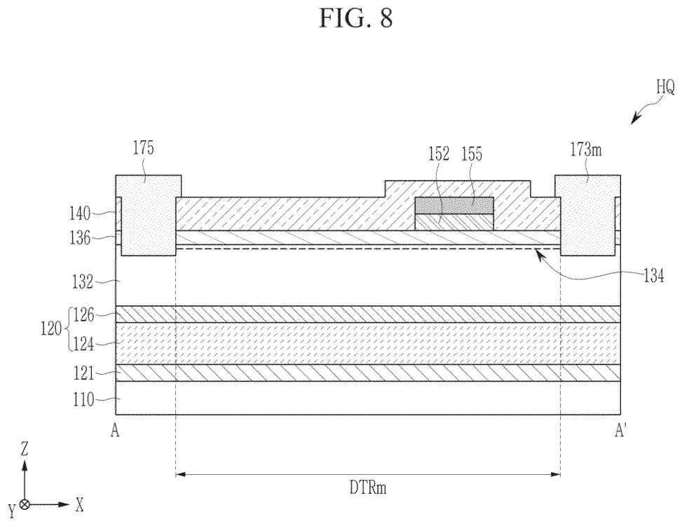

FIG. 6 shows a top plan view on a semiconductor device according to an embodiment of the present inventive concept. FIG. 7 and FIG. 8 show cross-sectional views with respect to a line A-A′ of FIG. 6. FIG. 7 shows a case when the semiconductor device according to an embodiment of the present inventive concept is turned off, and FIG. 8 shows a case when the semiconductor device according to an embodiment of the present inventive concept is turned on.

Referring to FIG. 6, the semiconductor device according to an embodiment of the present inventive concept may include a main device area MA and a peripheral circuit area PA.

The high electron mobility transistor HQ may be disposed in the main device area MA. For example, the high electron mobility transistor HQ of the semiconductor device according to an embodiment of the present inventive concept may be a normally-off high electron mobility transistor (HEMT). Without being limited thereto, the high electron mobility transistor HQ of the semiconductor device according to an embodiment of the present inventive concept may be a normally-on high electron mobility transistor. In an embodiment of the present inventive concept, the main device area MA may refer to a region in which the high electron mobility transistor HQ is arranged.

The peripheral circuit area PA may be spaced from the main device area MA. For example, the peripheral circuit area PA may be spaced from the main device area MA in a second direction (Y direction), but the present inventive concept is not limited thereto. For another example, the peripheral circuit area PA may be spaced from the main device area MA in the first direction (X direction), or may at least partially surround the sides of the main device area MA. Various other changes are possible. In an embodiment of the present inventive concept, a separation structure 160 may be disposed between the peripheral circuit area PA and the main device area MA, but the present inventive concept is not limited thereto.

The peripheral circuit area PA of the semiconductor device according to an embodiment of the present inventive concept may include elements that are electrically connected to the high electron mobility transistor HQ. For example, resisting elements 311 and 312, inverter circuits 321 and 322, and a first transistor Q1 may be disposed in the peripheral circuit area PA. The resisting elements 311 and 312 may correspond to the resistors R1 and R2 according to an embodiment of FIG. 4, and the inverter circuits 321 and 322 may correspond to the inverter circuits 321 and 322 in FIG. 5 which configure the digitizer circuit 320 according to an embodiment of FIG. 4 and FIG. 5.

Referring to FIG. 7, the high electron mobility transistor HQ of the semiconductor device according to an embodiment of the present inventive concept may include a channel layer 132, a barrier layer 136 disposed on the channel layer 132, a gate electrode 155 disposed on the barrier layer 136, a gate semiconductor layer 152 disposed between the barrier layer 136 and the gate electrode 155, a first protection layer 140 disposed on the barrier layer 136, and a main source electrode 173m and a main drain electrode 175 that are spaced apart from each other on the channel layer 132.

The channel layer 132 may form a channel between the main source electrode 173m and the main drain electrode 175, and two-dimensional electron gas (2DEG) 134 may be disposed inside the channel layer 132. The two-dimensional electron gas 134 may be a charge transport model used in the solid physics, it may represent a group of electrons moving freely in the two-dimension (e.g., x-y plane direction) but not moving in the other dimensions (e.g., z-direction) and tightly bound in the two-dimension. For example, the two-dimensional electron gas 134 may exist in a two-dimensional paper-Iike form in a three-dimensional space. The two-dimensional electron gas 134 may mainly appear in a semiconductor heterojunction structure, and may be generated at an interface between the channel layer 132 and the barrier layer 136 in the semiconductor device according to an embodiment of the present inventive concept. For example, the two-dimensional electron gas 134 may be generated in a portion of the channel layer 132 that is adjacent to the barrier layer 136. The channel layer 132 may include one or more materials from the Group III-V materials, for example, nitrides containing Al, Ga, In, B, or combinations thereof. The channel layer 132 may be a single layer or a multilayer. For example, the channel layer 132 may be AlₓIn_{y}Ga_{1-x-y}N (0≤x≤1, 0≤y≤1, x+y≤1). For example, the channel layer 132 may include AlN, GaN, InN, InGaN, AlGaN, AlInN, AlInGaN, or combinations thereof. The channel layer 132 may be a layer with doped impurities or a layer with undoped impurities. The thickness of the channel layer 132 may be about several hundred nm or less.

The channel layer 132 may be disposed on the substrate 110, and a seed layer 121 and a buffer layer 120 may be disposed between the substrate 110 and the channel layer 132. The substrate 110, the seed layer 121, and the buffer layer 120 may be used to form the channel layer 132, and may be omitted in some cases. For example, when the substrate made of GaN is used as the channel layer 132, at least one of the substrate 110, the seed layer 121, and the buffer layer 120 may be omitted. Considering that the price of the substrate made of GaN is relatively high, the channel layer 132 including GaN may be grown by using the substrate 110 made of Si. The lattice structure of Si and the lattice structure of GaN are different so it might not be easy to grow the channel layer 132 on the substrate 110. Accordingly, the seed layer 121 and the buffer layer 120 may be first grown on the substrate 110, and then the channel layer 132 may be grown on the buffer layer 120. For example, at least one of the substrate 110, the seed layer 121, and/or the buffer layer 120 may be removed from the final structure of the semiconductor device after being used in the manufacturing process.

The substrate 110 may include a semiconductor material. For example, the substrate 110 may include sapphire, Si, SiC, AlN, GaN, or combinations thereof. The substrate 110 may be a silicon on insulator (SOI) substrate. However, the material of substrate 110 is not limited to this, and any generally-used substrates may be applied. In some cases, the substrate 110 may include an insulating material. For example, several layers including the channel layer 132 may be formed on the semiconductor substrate, the semiconductor substrate may be removed, and may be replaced with an insulation substrate.

The seed layer 121 may be disposed on the substrate 110. Without being limited to this, another predetermined layer may be disposed between the substrate 110 and the seed layer 121. The seed layer 121 may serve as a seed for growing the buffer layer 120, and may be made of a crystal lattice structure that becomes the seed of the buffer layer 120. The buffer layer 120 may be disposed on the seed layer 121. Without being limited to this, other predetermined layers may be disposed between the seed layer 121 and the buffer layer 120. The seed layer 121 may include one or more materials from the Group III-V materials, for example nitrides containing Al, Ga, In, B, or combinations thereof. For example, the seed layer 121 may be AlₓIn_{y}Ga_{1-x-y}N (0≤x≤1, 0≤y≤1, x+y≤1). For example, the seed layer 121 may include AlN, GaN, InN, InGaN, AlGaN, AlInN, AlInGaN, or combinations thereof.

The buffer layer 120 may be disposed on the seed layer 121. The buffer layer 120 may be disposed between the seed layer 121 and the channel layer 132. The buffer layer 120 may alleviate the difference in a lattice constant and a thermal expansion coefficient between the seed layer 121 and the channel layer 132 or may prevent a leakage current from flowing through the channel layer 132. The buffer layer 120 may include one or more materials from the Group III-V materials, for example, nitrides containing Al, Ga, In, B, or combinations thereof. For example, the buffer layer 120 may be AlₓIn_{y}Ga_{1-x-y}N (0≤x≤1, 0≤y≤1, x+y≤1). For example, the buffer layer 120 may include AlN, GaN, InN, InGaN, AlGaN, AlInN, AlInGaN, or combinations thereof.

The buffer layer 120 of the semiconductor device according to an embodiment of the present inventive concept may include a superlattice layer 124, which is disposed on the seed layer 121, and a high resistance layer 126, which is disposed on the superlattice layer 124. The superlattice layer 124 and the high resistance layer 126 may be sequentially disposed on the substrate 110.

The superlattice layer 124 may be disposed on the seed layer 121. The superlattice layer 124 may be disposed on the seed layer 121. Without being limited to this, another predetermined layer may be disposed between the seed layer 121 and the super lattice layer 124. The superlattice layer 124 may alleviate the difference in the lattice constant and the thermal expansion coefficient between the substrate 110 and the channel layer 132, and thus, the tensile stress and the compressive stress generated between the substrate 110 and the channel layer 132 may be reduced, and the stress between the entire layers formed by growth in the final structure of the semiconductor device according to an embodiment of the present inventive concept may be relieved. The superlattice layer 124 may include one or more materials from the Group III-V materials, for example, nitrides containing Al, Ga, In, B, or combinations thereof. The superlattice layer 124 may be AlₓIn_{y}Ga_{1-x-y}N (0≤x≤1, 0≤y≤1, x+y≤1). For example, the superlattice layer 124 may include AlN, GaN, InN, InGaN, AlGaN, AlInN, AlInGaN, or combinations thereof.

In an embodiment of the present inventive concept, the superlattice layer 124 may be made of multilayer in which layers including different materials than each other are alternately stacked on each other. For example, the superlattice layer 124 may have a structure in which a layer made of AlGaN and a layer made of AlN are repeatedly stacked on each other. In other words, AlGaN/AlN/AlGaN/AlN/AlGaN/AlN may be sequentially stacked to form the superlattice layer. The number of the layers of AlGaN and GaN constituting the superlattice layer 124 may be variable, and the material constituting the superlattice layer 124 may vary in many ways. For another example, the superlattice layer 124 may have a structure in which a layer made of AlGaN and a layer made of GaN are repeatedly stacked. For example, AlGaN/GaN/AlGaN/GaN/AlGaN/GaN may be sequentially stacked to form the superlattice layer. In an embodiment of the present inventive concept, when the superlattice layer 124 includes GaN, InN, AlGaN, AlInN, InGaN, AlN, AlInGaN or combinations thereof, the superlattice layer 124 may have an N-type semiconductor characteristic in which the concentration of electrons is greater than the concentration of holes, but the present inventive concept is not limited thereto.

The high resistance layer 126 may be disposed on the superlattice layer 124. For example, the high resistance layer 126 may be disposed directly on the superlattice layer 124. Without being limited to this, another predetermined layer may be disposed between the superlattice layer 124 and the high resistance layer 126. The high resistance layer 126 may be disposed between the superlattice layer 124 and the channel layer 132. The high resistance layer 126 may prevent a semiconductor device according to an embodiment of the present inventive concept from being degraded by preventing a leakage current from flowing through the channel layer 132. The high resistance layer 126 may be made of a material with low conductivity so that the substrate 110 may be electrically insulated from the channel layer 132. The high resistance layer may include one or more materials from the Group III-V materials, for example, nitrides containing Al, Ga, In, B, or combinations thereof. The high resistance layer 126 may be AlₓIn_{y}Ga_{1-x-y}N (0≤x≤1, 0≤y≤1, x+y≤1). For example, the high resistance layer 126 may include AlN, GaN, InN, InGaN, AlGaN, AlInN, AlInGaN, or combinations thereof. The high resistance layer 126 may be a single layer or a multilayer. In an embodiment of the present inventive concept, when the high resistance layer 126 includes GaN, InN, AlGaN, AlInN, InGaN, AlN, AlInGaN or combinations thereof, the high resistance layer 126 may have an N-type semiconductor characteristic in which the concentration of the electrons is greater than the concentration of the holes, but the present inventive concept is not limited thereto.

The barrier layer 136 may be disposed on the channel layer 132. For example, the barrier layer 136 may be disposed directly on the channel layer 132. Without being limited to this, a predetermined additional layer may be disposed between the channel layer 132 and the barrier layer 136. The region of the channel layer 132 overlapping the portion of the barrier layer 136 that is between the main source electrode 173m and the main drain electrode 175 may be the main drift region DTRm. The main drift region DTRm may be disposed between main source electrode 173m and main drain electrode 175. The main drift region DTRm may represent the region in which carriers move when a potential difference occurs between the main source electrode 173m and the main drain electrode 175.

A semiconductor device according to an embodiment of the present inventive concept may be turned on/off depending on whether a voltage is applied to the gate electrode 155 and/or depending on the size of the voltage that is applied to the gate electrode 155, and accordingly, movement of the carriers in the main drift region DTRm may be performed or blocked.

The barrier layer 136 may include one or more materials from the Group III-V materials, for example, nitrides containing Al, Ga, In, B, or combinations thereof. For example, the barrier layer 136 may be AlₓIn_{y}Ga_{1-x-y}N (0≤x≤1, 0≤y≤1, x+y≤1). The barrier layer 136 may include GaN, InN, AlGaN, AlInN, InGaN, AlN, AlInGaN, or combinations thereof. An energy band gap of the barrier layer 136 may be controlled by a composition ratio of Al and/or In. The barrier layer 136 may be doped with predetermined impurities. The impurity doped in the barrier layer 136 may be a P-type dopant providing holes. For example, the impurity doped to the barrier layer 136 may be magnesium (Mg). The threshold voltage, on-resistance, etc. of the semiconductor device according to an embodiment of the present inventive concept may be adjusted by increasing or reducing the impurity doping concentration of the barrier layer 136

The barrier layer 136 may include a semiconductor material with characteristics that are different from that of the channel layer 132. The barrier layer 136 may differ from the channel layer 132 in at least one of polarization characteristics, energy band gap, or lattice constant. For example, barrier layer 136 may include a material with a different energy band gap from the channel layer 132. The barrier layer 136 may have a higher energy band gap than the channel layer 132 and may have a higher electrical polarizability than the channel layer 132. By this barrier layer 136, two-dimensional electron gas 134 may be induced in the channel layer 132, which has relatively low electrical polarizability. In this respect, the barrier layer 136 may also be referred to as a channel supply layer or a two-dimensional electron gas supply layer. The two-dimensional electron gas 134 may be formed in a portion of the channel layer 132 and may be disposed below the interface between the channel layer 132 and the barrier layer 136. The two-dimensional electron gas 134 may have very high electron mobility.

The barrier layer 136 may be a single layer or a multilayer. When the barrier layer 136 is a multilayer, the energy band gaps of the materials of the respective layers constituting the multilayer may be different from each other. The layers constituting the barrier layer 136 may be arranged so that the energy band gap may increase as approaching the channel layer 132.

The gate electrode 155 may be disposed on the barrier layer 136. The gate electrode 155 may overlap a predetermined region of the barrier layer 136 in the vertical direction (e.g., a thickness direction of the channel layer 132). The gate electrode 155 may overlap a portion of the main drift region DTRm of the channel layer 132 in the vertical direction (e.g., the thickness direction of the channel layer 132). The gate electrode 155 may be disposed between the main source electrode 173m and the main drain electrode 175. The gate electrode 155 may be spaced apart from the main source electrode 173m and the main drain electrode 175. For example, the gate electrode 155 may be disposed closer to the main source electrode 173m than main drain electrode 175. For example, the separation distance between the gate electrode 155 and the main source electrode 173m may be less than the separation distance between the gate electrode 155 and the main drain electrode 175, but the present inventive concept is not limited thereto. In an embodiment of the present inventive concept, the gate electrode 155 may refer to the gate electrode portion that is disposed in the main device area MA.

The gate electrode 155 may include a conductive material. For example, the gate electrode 155 may include a metal, a metal alloy, a conductive metal nitride, a metal silicide, a doped semiconductor material, a conductive metal oxide, or a conductive metal oxynitride. For example, the gate electrode 155 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbide (TiAlC-N), titanium aluminum carbide (TiAlC), titanium carbide (TIC), tantalum carbide (TaCN), tungsten (W), aluminum (AI), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but the present inventive concept is not limited thereto. The gate electrode 155 may be a single layer or a multilayer.

The gate semiconductor layer 152 may be disposed between the barrier layer 136 and the gate electrode 155. For example, the gate semiconductor layer 152 may be disposed on the barrier layer 136, and the gate electrode 155 may be disposed on the gate semiconductor layer 152. The gate electrode 155 may Schottky contact or ohmic contact the gate semiconductor layer 152. The gate semiconductor layer 152 may overlap the gate electrode 155 in the vertical direction (e.g., the thickness direction of the channel layer 132). For example, the gate semiconductor layer 152 may completely overlap the gate electrode 155 in the vertical direction (e.g., the thickness direction of the channel layer 132), and an upper surface of the gate semiconductor layer 152 may be covered by the gate electrode 155. For example, the gate semiconductor layer 152 may have substantially the same planar shape as the gate electrode 155. However, without being limited thereto, the gate electrode 155 may be disposed to cover at least a portion of the gate semiconductor layer 152.

The gate semiconductor layer 152 may be disposed between the main source electrode 173m and the main drain electrode 175. The gate semiconductor layer 152 may be spaced apart from the main source electrode 173m and the main drain electrode 175. The gate semiconductor layer 152 may be disposed closer to the main source electrode 173m than to the main drain electrode 175. For example, the separation distance between the gate semiconductor layer 152 and the main source electrode 173m may be less than the separation distance between the gate semiconductor layer 152 and the main drain electrode 175, but the present inventive concept is not limited thereto.

In an embodiment of the present inventive concept, the gate semiconductor layer 152 may overlap the gate electrode 155 in the vertical direction (e.g., the thickness direction of the channel layer 132). For example, the gate semiconductor layer 152 may completely overlap the gate electrode 155 in the vertical direction (e.g., the thickness direction of the channel layer 132). For example, a side of the gate semiconductor layer 152 may be substantially aligned with a side of the gate electrode 155. However, without being limited thereto, the gate semiconductor layer 152 may partially overlap the gate electrode 155.

The gate semiconductor layer 152 may include one or more materials from the Group III-V materials, for example, nitrides containing Al, Ga, In, B, or combinations thereof. For example, the gate semiconductor layer 152 may be AlₓIn_{y}Ga_{1-x-y}N (0≤x≤1, 0≤y≤1, x+y≤1). For example, the gate semiconductor layer 152 may include AlN, GaN, InN, InGaN, AlGaN, AlInN, AlInGaN, or combinations thereof. The gate semiconductor layer 152 may include a material with a different energy band gap from that of the barrier layer 136. For example, the gate semiconductor layer 152 may include GaN, and the barrier layer 136 may include AlGaN. The gate semiconductor layer 152 may be doped with a predetermined impurity. The impurity doped to the gate semiconductor layer 152 may be a P-type dopant providing holes. For example, the gate semiconductor layer 152 may include GaN to which the P-type impurity is doped. For example, the gate semiconductor layer 152 may be made of a p-GaN layer. Without being limited to this, the semiconductor layer 152 may be a p-AlGaN layer. The gate semiconductor layer 152 may be a single layer or a multilayer.

A depletion region DPR may be formed in the channel layer 132 by the gate semiconductor layer 152. The depletion region DPR may be disposed in the main drift region DTRm, and may have a width that is smaller than that of the main drift region DTRm. As the gate semiconductor layer 152, which has a different energy band gap from that of the barrier layer 136, is disposed on the barrier layer 136, the level of the energy band of the portion of the barrier layer 136 that overlaps the gate semiconductor layer 152 may increase. Accordingly, a depletion region DPR may be formed in a region of the channel layer 132 overlapping the gate semiconductor layer 152. The depletion region DPR may be a region in which the two-dimensional electron gas 134 is not formed or which has a lower concentration of electrons than other regions of the channel path of the channel layer 132. In other words, the depletion region DPR may represent a region where the flow of two-dimensional electron gas 134 is disconnected in the main drift region DTRm. As the depletion region DPR is generated, no current may flow between the main source electrode 173m and the main drain electrode 175, and the channel path may be blocked. Accordingly, the semiconductor device according to an embodiment of the present inventive concept may have a normally-off characteristic.

That is, the semiconductor device according to an embodiment of the present inventive concept may be a normally-off high electron mobility transistor (HEMT). As shown in FIG. 7, in a normal state where no voltage is applied to the gate electrode 155, the depletion region DPR may exist, and the semiconductor device according to an embodiment of the present inventive concept may be in an Off state. As shown in FIG. 8, when a voltage that is equal to or greater than a threshold voltage is applied to the gate electrode 155, the depletion region DPR may disappear, and the two-dimensional electron gas 134 might not be disconnected but may be connected in the main drift region DTRm. That is, the two-dimensional electron gas 134 may be formed throughout the channel path between the main source electrode 173m and the main drain electrode 175, and the semiconductor device according to an embodiment of the present inventive concept may be in an On state. To summarize, the semiconductor device according to an embodiment of the present inventive concept may include semiconductor layers with different electrical polarization characteristics from each other, and the semiconductor layer with relatively large polarizability may cause the two-dimensional electron gas 134 in another semiconductor layer hetero-contacting with it. This two-dimensional electron gas 134 may be used as a channel between the main source electrode 173m and the main drain electrode 175, and continuation or interruption of the flow of the two-dimensional electron gas 134 may be controlled by a bias voltage that is applied to the gate electrode 155. In the gate Off state, the flow of two-dimensional electron gas 134 may be blocked so no current may flow between the main source electrode 173m and the main drain electrode 175. As the flow of two-dimensional electron gas 134 may continue in the gate On state, the current may flow between the main source electrode 173m and the main drain electrode 175.

In the above, the case in which the semiconductor device according to an embodiment of the present inventive concept is a normally off high electron mobility transistor has been described, but the present inventive concept is not limited thereto. For example, the semiconductor device according to an embodiment of the present inventive concept may be a normally-on high electron mobility transistor. In the case of the normally-on high electron mobility transistor, the gate semiconductor layer 152 may be omitted, and accordingly the gate electrode 155 may be disposed directly on the barrier layer 136. For example, the gate electrode 155 may contact the barrier layer 136. In this structure, the two-dimensional electron gas 134 may be used as a channel while no voltage is applied to the gate electrode 155, and a current flow may be generated between the main source electrode 173m and the main drain electrode 175. When a negative voltage is applied to the gate electrode 155, a depletion region DPR in which the flow of the two-dimensional electron gas 134 is disconnected at a bottom of the gate electrode 155 may be generated.

The previously-described seed layer 121, the superlattice layer 124, the high resistance layer 126, the channel layer 132, the barrier layer 136, and the gate semiconductor layer 152 may be sequentially stacked on the substrate 110. In the semiconductor device according to an embodiment of the present inventive concept, at least one of the seed layer 121, the superlattice layer 124, the high resistance layer 126, the channel layer 132, the barrier layer 136, and/or the gate semiconductor layer 152 may be omitted. The seed layer 121, the superlattice layer 124, the high resistance layer 126, the channel layer 132, the barrier layer 136, and the gate semiconductor layer 152 may be made of the semiconductor material with a same base, and the composition ratios of the materials of the respective layers may be different in consideration of functions of the respective layers and performance of the semiconductor devices.

The first protection layer 140 may be disposed on the barrier layer 136 and the gate electrode 155. The first protection layer 140 may cover an upper surface and a lateral surface of the gate electrode 155 and a lateral surface of the gate semiconductor layer 152. For example, a lower surface of the first protection layer 140 may contact the barrier layer 136 and the gate electrode 155. Accordingly, the barrier layer 136, the gate semiconductor layer 152, and the gate electrode 155 may be protected by the first protection layer 140. Without being limited thereto, the gate electrode 155 may penetrate the first protection layer 140 and may be connected to the gate semiconductor layer 152, and the first protection layer 140 might not cover the upper surface of the gate electrode 155. In addition, the lower surface of the first protection layer 140 may contact the gate semiconductor layer 152. The first protection layer 140 may include an insulating material. For example, the first protection layer 140 may include an oxide such as SiO₂ or Al₂O₃. For another example, the first protection layer 140 may include a nitride such as SiN or an oxynitride such as SiON.

FIG. 7 and FIG. 8 show that the first protection layer 140 is a single layer, but without being limited thereto, the first protection layer 140 may be a multilayer including different materials.

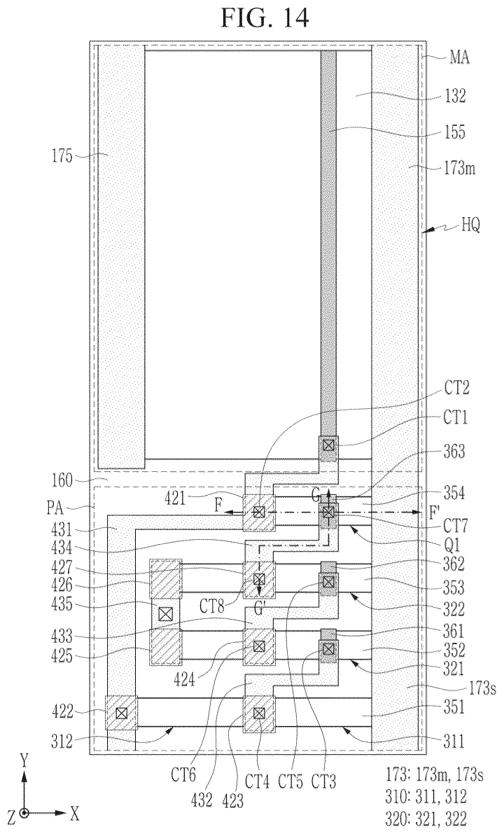

In embodiments of the present inventive concept, it may further include protection layers covering at least a portion of the first protection layer 140, the main source electrode 173m, and the main drain electrode 175. This will be described with reference to FIG. 14 to FIG. 16.

The main source electrode 173m and the main drain electrode 175 may be disposed on the channel layer 132. For example, the main source electrode 173m and the main drain electrode 175 may directly contact the channel layer 132 and may be electrically connected to the channel layer 132. The main source electrode 173m may represent the portion of the source electrode 173 that is disposed in the main device area MA.

The main source electrode 173m and the main drain electrode 175 may extend in the second direction (Y direction). The main source electrode 173m and the main drain electrode 175 may be spaced apart from each other, and the gate electrode 155 and the gate semiconductor layer 152 may be disposed between the main source electrode 173m and the main drain electrode 175. The gate electrode 155 and the gate semiconductor layer 152 may be spaced apart from the main source electrode 173m and the main drain electrode 175. For example, the main source electrode 173m may be electrically connected to the channel layer 132 on one side of the gate electrode 155, and the main drain electrode 175 may be electrically connected to the channel layer 132 on another side (e.g., an opposite side) of the gate electrode 155. The main source electrode 173m and the main drain electrode 175 may be disposed outside the main drift region DTRm of the channel layer 132. A boundary between the main source electrode 173m and the channel layer 132 may be one side edge of the main drift region DTRm. In a like way, the boundary between the main drain electrode 175 and the channel layer 132 may be another edge of the main drift region DTRm.

Without being limited to this, the main source electrode 173m and the main drain electrode 175 might not be disposed on an exterior side of the main drift region DTRm of the channel layer 132. For example, the channel layer 132 might not be recessed, and the main source electrode 173m and the main drain electrode 175 may be disposed on the upper surface of the channel layer 132. In this case, the lower surfaces of the main source electrode 173m and the main drain electrode 175 may contact the upper surface of the channel layer 132. The portions of the channel layer 132 contacting the main source electrode 173m and the main drain electrode 175 may be doped at a high concentration. The carriers having passed through the two-dimensional electron gas 134 may pass through the portion of the channel layer 132 doped at a high concentration, that is, the upper portion of the two-dimensional electron gas 134, and may be transmitted to the main source electrode 173m and the main drain electrode 175. The main source electrode 173m and the main drain electrode 175 might not directly contact the two-dimensional electron gas 134 in the horizontal direction. Here, the horizontal direction may represent a direction that is parallel to the upper surface of the channel layer 132 or the barrier layer 136.

For example, a trenches penetrating the first protection layer 140 and the barrier layer 136 and recessing the upper surface of the channel layer 132 may be spaced apart from each other on opposite sides of the gate electrode 155. The main source electrode 173m and the main drain electrode 175 may be disposed in the trenches that are disposed on the opposite sides of the gate electrode 155. The main source electrode 173m and the main drain electrode 175 may fill their corresponding trench. The main source electrode 173m and the main drain electrode 175 may contact the channel layer 132 and the barrier layer 136 while in their corresponding trench. The channel layer 132 may form a lower surface and a side wall of each trench, and the barrier layer 136 may form the side wall of each trench. Accordingly, the main source electrode 173m and the main drain electrode 175 may contact the upper surface and the lateral surface of the channel layer 132. The main source electrode 173m and the main drain electrode 175 may be in contact the lateral surface of the barrier layer 136. That is, the main source electrode 173m and the main drain electrode 175 may cover the lateral surfaces of the channel layer 132 and the barrier layer 136.

In an embodiment of the present inventive concept, the main source electrode 173m and the main drain electrode 175 may cover at least a portion of the lateral surface of the first protection layer 140. For example, the main source electrode 173m and the main drain electrode 175 may cover the lateral surface of the first protection layer 140. The upper surfaces of the main source electrode 173m and the main drain electrode 175 may protrude beyond the upper surface of the first protection layer 140. At least one of the main source electrode 173m and/or the main drain electrode 175 may cover at least a portion of the upper surface of the first protection layer 140. However, without being limited thereto, the main source electrode 173m and the main drain electrode 175 may cover at least a portion of the lateral surface of the first protection layer 140 and might not cover the remaining portion of the lateral surface of the first protection layer 140. In this case, the remaining part of the first protection layer 140 may be disposed on the upper surfaces of the main source electrode 173m and the main drain electrode 175.

The main source electrode 173m and the main drain electrode 175 may include a conductive material. For example, each of the main source electrode 173m and the main drain electrode 175 may include a metal, a metal alloy, a conductive metal nitride, a metal silicide, a doped semiconductor material, a conductive metal oxide, or a conductive metal oxynitride. For example, the main source electrode 173m and main drain electrode 175 may include titanium nitride (TIN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbide (TiAlC-N), titanium aluminum carbide (TiAlC), titanium carbide (TIC), tantalum carbide (TaCN), tungsten (W), aluminum (AI), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but it is not limited thereto. The main source electrode 173m and the main drain electrode 175 may be a single layer or a multilayer. The main source electrode 173m and the main drain electrode 175 may ohmic contact the channel layer 132. The region of the channel layer 132 contacting the main source electrode 173m and the main drain electrode 175 may be doped at a relatively higher concentration than the other regions of the channel layer 132.

FIG. 7 and FIG. 8 show that the semiconductor device according to an embodiment of the present inventive concept includes a pair of the main source electrode 173m and the main drain electrode 175, but the number of the main source electrode 173m and the main drain electrode 175 is not limited thereto. For example, the main source electrode 173m may include source electrodes that are sequentially stacked in the vertical direction (e.g., the thickness direction of the channel layer 132) on the channel layer 132, and the main drain electrode 175 may include drain electrodes that are sequentially stacked in the vertical direction (e.g., the thickness direction of the channel layer 132) on the channel layer 132. In addition, the main source electrode 173m and the main drain electrode 175 may respectively include at least three layers.

The semiconductor device according to an embodiment of the present inventive concept may further include a field dispersing layer that covers at least a portion of the first protection layer 140.

The field dispersing layer may be disposed between the main source electrode 173m and the main drain electrode 175. The field dispersing layer may cover the gate electrode 155. The field dispersing layer may overlap the gate electrode 155 in the vertical direction (e.g., the thickness direction of the channel layer 132). The field dispersing layer may be electrically connected to the main source electrode 173m. For example, field dispersing layer may be connected to the main source electrode 173m. The field dispersing layer may include the same material as the main source electrode 173m, and may be disposed on the same layer as the main source electrode 173m. The field dispersing layer may be simultaneously formed with the main source electrode 173m in the same process. For example, the boundary between the field dispersing layer and the main source electrode 173m might not be clear, and the field dispersing layer may be formed integrally with the main source electrode 173m. Without being limited to this, the field dispersing layer may be a component that is separated from the main source electrode 173m. The field dispersing layer may be disposed on a different layer from the main source electrode 173m and may be formed in a different process.

The field dispersing layer may serve to disperse the electric field that is concentrated around the gate electrode 155. For example, in the gate Off state, the two-dimensional electron gas 134 with very high concentration may be disposed in a portion of the channel layer 132 that is disposed between the gate electrode 155 and the main source electrode 173m and in a portion of the channel layer 132 that is disposed between the gate electrode 155 and the main drain electrode 175. An electric field may be concentrated on the gate electrode 155 or the gate semiconductor layer 152. In addition, the gate electrode 155 and the gate semiconductor layer 152 may be vulnerable to electric fields, so when electric fields are concentrated, a leakage current may increase and a breakdown voltage of the high electron mobility transistor HQ may decrease. The electric field concentrated around the gate electrode 155 or the gate semiconductor layer 152 may be dispersed by the field dispersing layer so the leakage current may be reduced and the breakdown voltage may be increased.

A structure of an electrostatic discharge protection circuit of the semiconductor device according to an embodiment of the present inventive concept will be described with reference to FIG. 6 and FIG. 9 to FIG. 12.

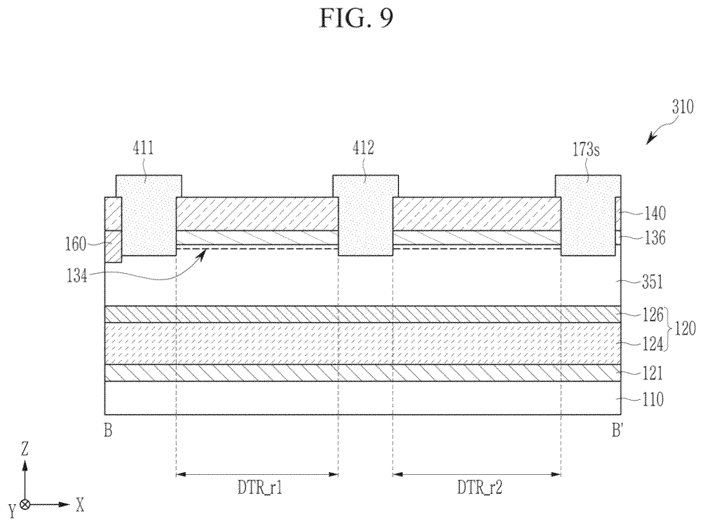

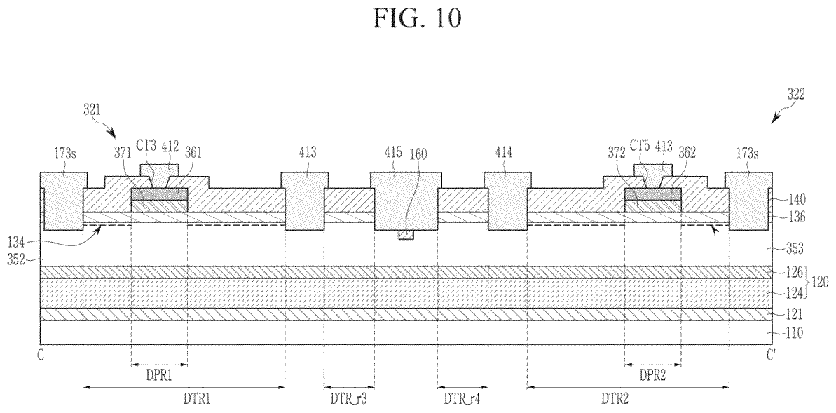

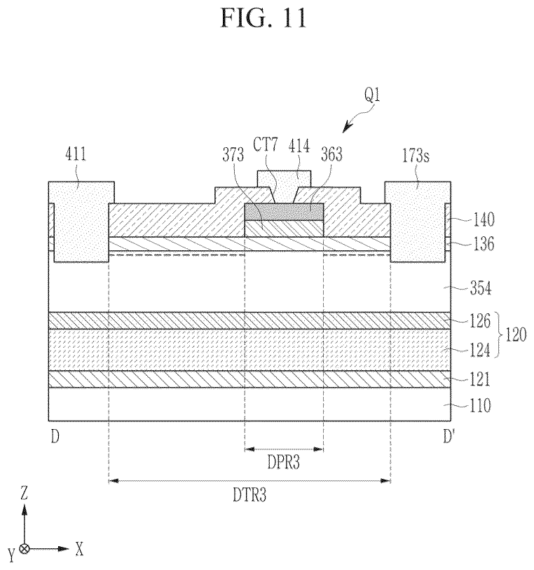

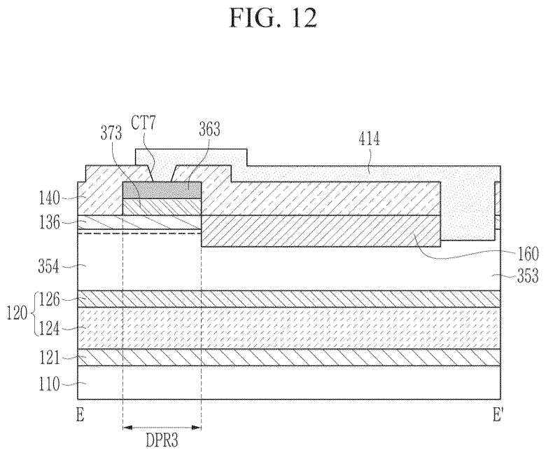

FIG. 9 shows a cross-sectional view with respect to a line B-B′ of FIG. 6. FIG. 10 shows a cross-sectional view with respect to a line C-C′ of FIG. 6. FIG. 11 shows a cross-sectional view with respect to a line D-D′ of FIG. 6. FIG. 12 shows a cross-sectional view with respect to a line E-E′ of FIG. 6.

Referring to FIG. 6, the semiconductor device may include resisting elements 311 and 312, inverter circuits 321 and 322, and a first transistor Q1 connected to the high electron mobility transistor HQ. In an embodiment of the present inventive concept, the resisting elements 311 and 312 may correspond to the resistors R1 and R2 of FIG. 4 of the voltage dividing circuit 320 of FIG. 4 according to an embodiment of the present inventive concept.

Referring to FIG. 9, the resisting elements 311 and 312 of the semiconductor device according to an embodiment of the present inventive concept may include a first channel pattern 351 including drift resistance regions DTR_r1 and DTR_r2 with the two-dimensional electron gas, a barrier layer 136 disposed on the first channel pattern 351, a sub-source electrode 173s disposed on the first channel pattern 351, a first connection wire 411 connecting the gate electrode 155 and the first channel pattern 351 to each other, and a second connection wire 412 disposed between the first connection wire 411 and the sub-source electrode 173s on the first channel pattern 351.

The first channel pattern 351 may be disposed on the substrate 110. The first channel pattern 351 may be a layer for forming a channel between the sub-source electrode 173s and the first connection wire 411, and the two-dimensional electron gas (2DEG) 134 may be disposed in the first channel pattern 351. The two-dimensional electron gas 134 may be generated at the interface between the first channel pattern 351 and the barrier layer 136 in the semiconductor device according to an embodiment of the present inventive concept. For example, the two-dimensional electron gas 134 may be generated in the portion of the first channel pattern 351 that is adjacent to the barrier layer 136. In an embodiment of the present inventive concept, the first channel pattern 351 may be disposed in the peripheral circuit area PA and may represent a portion of the channel layer 132 constituting the resisting elements 311 and 312.

In an embodiment of the present inventive concept, the first channel pattern 351 may be integrally formed with the channel layer 132 of the high electron mobility transistor HQ by the same process. The first channel pattern 351 may be disposed on the same layer as the channel layer 132. The lower surface of the first channel pattern 351 may be disposed on the same level as the lower surface of channel layer 132, and the upper surface of the first channel pattern 351 may be disposed on the same level as the upper surface of channel layer 132. That is, the distance between the upper surface of the substrate 110 and the lower surface of the first channel pattern 351 may be substantially the same as the distance between the lower surface of the channel layer 132 and the upper surface of the substrate 110. The distance between the upper surface of the substrate 110 and the upper surface of the first channel pattern 351 may be substantially the same as the distance between the upper surface of the channel layer 132 and the upper surface of the substrate 110. The thickness of the first channel pattern 351 in the third direction (Z direction) may be substantially the same as the thickness of the channel layer 132 in the third direction (Z direction), but is not limited thereto. In an embodiment of the present inventive concept, the first channel pattern 351 may be disposed on one side of the channel layer 132. For example, the first channel pattern 351 may be disposed on one side of the channel layer 132 in the second direction (Y direction), but the present inventive concept is not limited thereto.

The first channel pattern 351 may include the same material as the channel layer 132 and may be disposed in the main device area MA. As an example, the first channel pattern 351 may include one or more materials from the Group III-V materials, for example, nitrides containing Al, Ga, In, B, or combinations thereof.

The first channel pattern 351 may be disposed on the substrate 110, and the seed layer 121 and the buffer layer 120 may be disposed between the substrate 110 and the first channel pattern 351. The substrate 110, the seed layer 121, and the buffer layer 120 are for forming the first channel pattern 351, and may be omitted in some cases. In an embodiment of the present inventive concept, the substrate 110, the seed layer 121, and the buffer layer 120 that are disposed in the peripheral circuit area PA may be integrally formed with the substrate 110, the seed layer 121, and the buffer layer 120 that are disposed in the main device area MA by the same process.

The barrier layer 136 may be disposed on the first channel pattern 351. For example, the barrier layer 136 may be disposed directly on the first channel pattern 351. Without being limited to this, another predetermined layer may be disposed between the first channel pattern 351 and the barrier layer 136. The region of the first channel pattern 351 overlapping the barrier layer 136 may be a drift region. For example, the barrier layer 136 may be different from the first channel pattern 351 in at least one of the polarization characteristic, the energy band gap, or the lattice constant, so two-dimensional electron gas 134 may be generated to the first channel pattern 351 with relatively low electrical polarizability by the barrier layer 136. For example, the two-dimensional electron gas 134 may be in the first channel pattern 351 and may be adjacent to the barrier layer 136.

The first channel pattern 351 may include drift resistance regions DTR_r1 and DTR_r2. The drift resistance regions DTR_r1 and DTR_r2 may represent a region from one side of the first channel pattern 351 that is in contact with the sub-source electrode 173s to the other side of the first channel pattern 351 that is in contact with the second connection wire 412 and a region from one side of the first channel pattern 351 that is in contact with the second connection wire 412 to the other side of the first channel pattern 351 that is in contact with the first connection wire 411. For example, the boundary where first connection wire 411 meets the first channel pattern 351 may be the one side edge of the first drift resistance region DTR_r1, and the boundary where one side of second connection wire 412 meets the first channel pattern 351 may be another edge of the first drift resistance region DTR_r1.

In addition, the boundary where the other side of the second connection wire 412 meets the first channel pattern 351 may be one side edge of the second drift resistance region DTR_r2, and the boundary where the sub-source electrode 173s meets the first channel pattern 351 may be another edge of the second drift resistance region DTR_r2. The drift resistance regions DTR_r1 and DTR_r2 may represent regions in which the carriers move in the first channel pattern 351. In an embodiment of the present inventive concept, the drift resistance regions DTR_r1 and DTR_r2 may extend in the first direction (X direction), but the present inventive concept is not limited thereto.

In an embodiment of the present inventive concept, the drift resistance regions DTR_r1 and DTR_r2 may have resistance components. In other words, the drift resistance regions DTR_r1 and DTR_r2 may function as resistors with a predetermined resistance. In an embodiment of the present inventive concept, the resistance of the first drift resistance region DTR_r1 may correspond to the size of the first resistor R1 in FIG. 4 according to an embodiment of FIG. 4, and the resistance of the second drift resistance region DTR_r2 may correspond to the size of the second resistor R2 in FIG. 4 according to an embodiment of FIG. 4. However, without being limited thereto, the resistance of the resisting elements 311 and 312 according to an embodiment of FIG. 4 may further include other components with a resistance. For example, the first resistor R1 in FIG. 4 may further include contact resistance between the first connection wire 411 and the first channel pattern 351 and contact resistance between the second connection wire 412 and the first channel pattern 351. The second resistor R2 in FIG. 4 may further include contact resistance between the second connection wire 412 and the first channel pattern 351 and contact resistance between the sub-source electrode 173s and the first channel pattern 351. In an embodiment of the present inventive concept, the resistance of the first resistor R1 in FIG. 4 and the resistance of the second resistor R2 in FIG. 4 may be determined according to lengths of the first drift resistance region DTR_r1 and the second drift resistance region DTR_r2. For example, a ratio of the first resistor R1 of FIG. 4 and the second resistor R2 of FIG. 4 may be determined according to the ratio of the length of the first drift resistance region DTR_r1 and the length of the second drift resistance region DTR_r2 in the first direction (X direction).

The sub-source electrode 173s may be disposed on one side of the first channel pattern 351. The sub-source electrode 173s may contact the first channel pattern 351 and may be electrically connected to the first channel pattern 351. The sub-source electrode 173s may be disposed outside the drift resistance regions DTR_r1 and DTR_r2. The interface between the sub-source electrode 173s and the first channel pattern 351 may be one side edge of the second drift resistance region DTR_r2. In an embodiment of the present inventive concept, the sub-source electrode 173s may represent the portion of the source electrode 173 disposed in the peripheral circuit area PA.

In an embodiment of the present inventive concept, the sub-source electrode 173s may be disposed in a space in which at least a portion of the first channel pattern 351 is recessed. The sub-source electrode 173s may penetrate the barrier layer 136 and may contact the lateral surface of the first channel pattern 351. The sub-source electrode 173s may be electrically connected to the second drift resistance region DTR_r2. Without being limited to this, the first channel pattern 351 might not be recessed, and the sub-source electrode 173s may be disposed on the upper surface of the first channel pattern 351.

The sub-source electrode 173s may cover at least a portion of the upper surface of the first protection layer 140, but is not limited thereto. The sub-source electrode 173s may cover at least a portion of the lateral surface of the first protection layer 140. For example, the sub-source electrode 173s may cover the lateral surface of the first protection layer 140. The upper surface of the sub-source electrode 173s may protrude beyond the upper surface of the first protection layer 140.

The sub-source electrode 173s may be connected to the main source electrode 173m. The sub-source electrode 173s may be integrally formed with the main source electrode 173m and the main drain electrode 175 by the same process. For example, the sub-source electrode 173s may be disposed on the same layer as the main source electrode 173m.

The sub-source electrode 173s may include a conductive material. The sub-source electrode 173s may include the same material as the main source electrode 173m and the main drain electrode 175. For example, the sub-source electrode 173s may include a metal, a metal alloy, a conductive metal nitride, a metal silicide, a doped semiconductor material, a conductive metal oxide, or a conductive metal oxynitride. The sub-source electrode 173s may be a single layer or a multilayer. The sub-source electrode 173s may ohmic contact the first channel pattern 351. The region of the first channel pattern 351 may contact the sub-source electrode 173s may be doped with a relatively high concentration compared to other regions of the first channel pattern 351, but the present inventive concept is not limited thereto.

The first connection wire 411 may electrically connect the gate electrode 155 of the high electron mobility transistor HQ and the first channel pattern 351. The first connection wire 411 may be electrically connected to the gate electrode 155 through a first contact via CT1 penetrating the first protection layer 140, and may be electrically connected to the first channel pattern 351 by penetrating the first protection layer 140 and the barrier layer 136. The first connection wire 411 may overlap the gate electrode 155 in the vertical direction (e.g., the thickness direction of the channel layer 132). At least a portion of the first connection wire 411 may overlap the separation structure 160 in the vertical direction (e.g., the thickness direction of the channel layer 132), but the present inventive concept is not limited thereto.

In addition, the first connection wire 411 may also be electrically connected to the fourth channel pattern 354. This will be described later in connection with the first transistor Q1.

The first connection wire 411 may be disposed on one side of the first channel pattern 351. The first connection wire 411 may contact the first channel pattern 351, and may be electrically connected to the first channel pattern 351. The first connection wire 411 may be disposed outside the drift resistance regions DTR_r1 and DTR_r2. The boundary between the first connection wire 411 and the first channel pattern 351 may be one side edge of the first drift resistance region DTR_r1. In an embodiment of the present inventive concept, the first connection wire 411 may be disposed in the space in which at least a portion of the first channel pattern 351 is recessed. The first connection wire 411 may penetrate the barrier layer 136 and may contact the lateral surface of the first channel pattern 351. The first connection wire 411 may be electrically connected to the first drift resistance region DTR_r1.

The first connection wire 411 may include a conductive material. The first connection wire 411 may include substantially the same material as the sub-source electrode 173s and/or the gate electrode 155, but the present inventive concept is not limited thereto. For example, the first connection wire 411 may include a metal, a metal alloy, a conductive metal nitride, a metal silicide, a doped semiconductor material, a conductive metal oxide, or a conductive metal oxynitride.

The second connection wire 412 electrically connect the first channel pattern 351 and the first gate electrode 155 of the first inverter circuit 321. The second connection wire 412 may be electrically connected to the first gate electrode 155 through the third contact via CT3 penetrating the first protection layer 140, and may penetrate the first protection layer 140 and the barrier layer 136. In addition, the second connection wire 412 may be electrically connected to the first channel pattern 351. In an embodiment of the present inventive concept. the second connection wire 412 may overlap the first gate electrode 155 in the vertical direction (e.g., the thickness direction of the channel layer 132). At least a portion of the second connection wire 412 may overlap the separation structure 160 in the vertical direction (e.g., the thickness direction of the channel layer 132), but the present inventive concept is not limited thereto.

As shown in FIG. 9, the second connection wire 412 may be disposed between the first connection wire 411 and the sub-source electrode 173s on the first channel pattern 351. The boundary between the second connection wire 412 and the first channel pattern 351 may be the edges of the drift resistance regions DTR_r1 and DTR_r2. In an embodiment of the present inventive concept, the second connection wire 412 may be disposed in the space in which at least a portion of the first channel pattern 351 is recessed. The second connection wire 412 may penetrate the barrier layer 136 and may contact the lateral surface of the first channel pattern 351. The second connection wire 412 may be electrically connected to the first drift resistance region DTR_r1 and the second drift resistance region DTR_r2.

In an embodiment of the present inventive concept, contact electrodes may be disposed between the first connection wire 411 and the second connection wire 412 and between the second connection wire 412 and the sub-source electrode 173s on the first channel pattern 351. The contact electrodes penetrate the first protection layer 140 and the barrier layer 136 and may be disposed on the first channel pattern 351. The drift resistance regions DTR_r1 and DTR_r2 might not be formed on the portion of the first channel pattern 351 contacting the contact electrodes, and the carriers may move through the drift resistance regions DTR_r1 and DTR_r2 and the contact electrodes.

Inverter circuits of a semiconductor device according to an embodiment of the present inventive concept will now be described with reference to FIG. 6 and FIG. 10.

Referring to FIG. 6 and FIG. 10, the inverter circuits 321 and 322 of the semiconductor device according to an embodiment of the present inventive concept may include a first inverter circuit 321 and a second inverter circuit 322, and a fifth connection wire 415 for connecting the first inverter circuit 321 and the second inverter circuit 322.

The first inverter circuit 321 may include a second channel pattern 352, a barrier layer 136 disposed on the second channel pattern 352, a sub-source electrode 173s disposed on the second channel pattern 352, a first gate electrode 361 disposed on the barrier layer 136, a first gate semiconductor layer 371 disposed between the barrier layer 136 and the first gate electrode 361, and a third connection wire 413 for connecting the second channel pattern 352 and the second gate electrode 362 to each other.

The second inverter circuit 322 may include a third channel pattern 353, a barrier layer 136 disposed on the third channel pattern 353, a sub-source electrode 173s disposed on the third channel pattern 353, a second gate electrode 362 disposed on the barrier layer 136, a second gate semiconductor layer 372 disposed between the barrier layer 136 and the second gate electrode 362, and a fourth connection wire 414 for connecting the third channel pattern 353 and a third gate electrode 363 to each other.

In an embodiment of the present inventive concept, the first inverter circuit 321 and the second inverter circuit 322 may respectively include a resisting element and a transistor. For example, the first inverter circuit 321 may include a third resistor R3 of FIG. 5 and a second transistor Q2 of FIG. 5, and the second inverter circuit 322 may include a fourth resistor R4 of FIG. 5 and a third transistor Q3 of FIG. 5. The third resistor R3 of FIG. 5 may include a resistance component of a third drift resistance region DTR_r3 of the second channel pattern 352 disposed between the fifth connection wire 415 and the third connection wire 413. In addition, a source of the second transistor Q2 of FIG. 5 may correspond to the sub-source electrode 173s, and a drain may correspond to the third connection wire 413. A gate may correspond to the first gate electrode 361. The fourth resistor R4 of FIG. 5 may include a resistance component of a fourth drift resistance region DTR_r4 of the third channel pattern 353 disposed between the fifth connection wire 415 and the fourth connection wire 414. A source of the third transistor Q3 of FIG. 5 may correspond to the sub-source electrode 173s, and a drain may correspond to the fourth connection wire 414. A gate may correspond to the second gate electrode 362.

The second and third channel patterns 352 and 353 may be disposed on the substrate 110. The second and third channel patterns 352 and 353 may be layers for forming a channel between the sub-source electrode 173s and the fifth connection wire 415, and the two-dimensional electron gas (2DEG) 134 may be disposed in the second and third channel patterns 352 and 353. The two-dimensional electron gas 134 may be generated on the interfaces between the second channel pattern 352 and the barrier layer 136 and between the third channel pattern 353 and the barrier layer 136 in the semiconductor device according to an embodiment of the present inventive concept. For example, the two-dimensional electron gas 134 may be generated around the barrier layer 136 in the second and third channel patterns 352 and 353. In an embodiment of the present inventive concept, the second and third channel patterns 352 and 353 may represent a portion of the channel layer 132 disposed in the peripheral circuit area PA and configuring the first and second inverter circuits 321 and 322.

In an embodiment of the present inventive concept, the second channel pattern 352 may be spaced apart from the third channel pattern 353. For example, the second channel pattern 352 and the third channel pattern 353 may be spaced apart from each other in the second direction (Y direction). The separation structure 160 may be disposed between the second channel pattern 352 and the third channel pattern 353. The second channel pattern 352 may be disposed between the first channel pattern 351 and the channel layer 132. The second channel pattern 352 may be separated from the third channel pattern 353 by the separation structure 160.

In an embodiment of the present inventive concept, the second and third channel patterns 352 and 353 may be integrally formed with the channel layer 132 and the first channel pattern 351 of the high electron mobility transistor HQ by the same process. Other descriptions of the second and third channel patterns 352 and 353 substantially correspond to those of the first channel pattern 351 so they will be omitted. The barrier layer 136 may be disposed on the second and third channel patterns 352 and 353. For example, the barrier layer 136 may be disposed directly on the second and third channel patterns 352 and 353. Without being limited to this, another predetermined layer may be disposed between the second and third channel patterns 352 and 353 and the barrier layer 136. The region of the second and third channel patterns 352 and 353 overlapping the barrier layer 136 may be a drift region. For example, the barrier layer 136 may be different from the second and third channel patterns 352 and 353 in at least one of the polarization characteristic, the energy band gap, or the lattice constant so the two-dimensional electron gas 134 may be generated to the second and third channel patterns 352 and 353 with relatively low electrical polarizability by the barrier layer 136.

As shown in FIG. 10, the second and third channel patterns 352 and 353 may include the drift regions DTR1 and DTR2 and the drift resistance regions DTR_r3 and DTR_r4. For example, the second channel pattern 352 may include a first drift region DTR1 extending from one side of the second channel pattern 352 contacting the sub-source electrode 173s to the other side of the second channel pattern 352 contacting the third connection wire 413, and a third drift resistance region DTR_r3 extending from one side of the second channel pattern 352 contacting the third connection wire 413 to the other side of the second channel pattern 352 contacting the fifth connection wire 415. The third channel pattern 353 may include a fourth drift resistance region DTR_r4 extending from one side of the third channel pattern 353 contacting the fifth connection wire 415 to the other side of the third channel pattern 353 contacting the fourth connection wire 414, and a second drift region DTR2 extending from one side of the third channel pattern 353 contacting the fourth connection wire 414 to the other side of the third channel pattern 353 contacting the sub-source electrode 173s. The drift regions DTR1 and DTR2 and the drift resistance regions DTR_r3 and DTR_r4 may represent regions in which the carriers move in the second and third channel patterns 352 and 353. In an embodiment of the present inventive concept, the drift regions DTR1 and DTR2 and the drift resistance regions DTR_r3 and DTR_r4 may extend in the first direction (X direction), but the present inventive concept is not limited thereto.

In an embodiment of the present inventive concept, the first inverter circuit 321 may be turned on/off according to the voltage applied to the first gate electrode 361, and the movement of the carriers may be allowed or blocked in the first drift region DTR1. The second inverter circuit 322 may be turned on/off according to the voltage applied to the second gate electrode 362 so the movement of the carriers may be allowed or blocked in the second drift region DTR2.

In an embodiment of the present inventive concept, the third and fourth drift resistance regions DTR_r3 and DTR_r4 may have resistance components. That is, the third and fourth drift resistance regions DTR_r3 and DTR_r4 may function as resistors with predetermined resistance. In an embodiment of the present inventive concept, resistance of the third drift resistance region DTR_r3 may correspond to the size of the third resistor R3 of FIG. 5 according to an embodiment of FIG. 5, and resistance of the fourth drift resistance region DTR_r4 may correspond to the size of the fourth resistor R4 of FIG. 5 according to an embodiment of FIG. 5. However, without being limited thereto, the third resistor R3 of FIG. 5 and the fourth resistor R4 of FIG. 5 according to an embodiment of FIG. 5 may further include other resistance components. For example, the third resistor R3 of FIG. 5 may further include contact resistance, which is between the third connection wire 413 and the second channel pattern 352, and contact resistance between the fifth connection wire 415 and the second channel pattern 352. The fourth resistor R4 of FIG. 5 may further include contact resistance, which is between the fifth connection wire 415 and the third channel pattern 353, and contact resistance, which is between the fourth connection wire 414 and the third channel pattern 353. In an embodiment of the present inventive concept, the sizes of the third resistor R3 of FIG. 5 and the fourth resistor R4 of FIG. 5 may be determined by the lengths of the third drift resistance region DTR_r3 and the fourth drift resistance region DTR_r4. For example, a ratio of the third resistor R3 of FIG. 5 and the fourth resistor R4 of FIG. 5 may be determined by the ratio of the lengths of the third drift resistance region DTR_r3 and the fourth drift resistance region DTR_r4 in the first direction (X direction).

The first and second gate electrodes 361 and 362 may be disposed on the barrier layer 136. For example, the first gate electrode 361 may be disposed on a portion of the barrier layer 136 that is disposed on the second channel pattern 352, and the second gate electrode 362 may be disposed on a portion of the barrier layer 136 that is disposed on the third channel pattern 353. The first gate electrode 361 may be disposed between the third connection wire 413 and the sub-source electrode 173s, and the second gate electrode 362 may be disposed between the fourth connection wire 414 and the sub-source electrode 173s.

The first gate electrode 361 may overlap the second channel pattern 352 in the third direction (Z direction), and the second gate electrode 362 may overlap the third channel pattern 353 in the third direction (Z direction). The first gate electrode 361 may overlap a portion of the first drift region DTR1 in the third direction (Z direction), and the second gate electrode 362 may overlap a portion of the second drift region DTR2 in the third direction (Z direction). The first gate electrode 361 may be spaced apart from the second gate electrode 362. For example, the first gate electrode 361 and the second gate electrode 362 may be spaced apart in the second direction (Y direction), but the present inventive concept not limited thereto. Other descriptions of the first and second gate electrodes 361 and 362 substantially correspond to those of the gate electrode 155 given according to the embodiment of FIG. 7 and FIG. 8, so they will be omitted.

The first and second gate electrodes 361 and 362 may include a conductive material. The first and second gate electrodes 361 and 362 may include the same material as the gate electrode 155 of the high electron mobility transistor HQ. The first gate electrode 361 and the second gate electrode 362 may include the same material, but the present inventive concept is not limited thereto. For example, the first and second gate electrodes 361 and 362 may include a metal, a metal alloy, a conductive metal nitride, a metal silicide, a doped semiconductor material, a conductive metal oxide, or a conductive metal oxynitride.

The first gate semiconductor layer 371 may be disposed between the barrier layer 136 and the first gate electrode 361. That is, the first gate semiconductor layer 371 may be disposed on the barrier layer 136, and the first gate electrode 361 may be disposed on the first gate semiconductor layer 371. The first gate electrode 361 may Schottky contact or ohmic contact the first gate semiconductor layer 371. The second gate semiconductor layer 372 may be disposed between the barrier layer 136 and the second gate electrode 362. That is, second gate semiconductor layer 372 may be disposed on the barrier layer 136, and the second gate electrode 362 may be disposed on the second gate semiconductor layer 372. The second gate electrode 362 may Schottky contact or ohmic contact the second gate semiconductor layer 372.

The first and second gate semiconductor layers 371 and 372 may include the same material as the gate semiconductor layer 152 of the high electron mobility transistor HQ. The first gate semiconductor layer 371 and the second gate semiconductor layer 372 may include the same material, but the present inventive concept is not limited thereto. For example, the first and second gate semiconductor layers 371 and 372 may include one or more materials of the Group III-V materials, for example, nitrides including Al, Ga, In, B, or combinations thereof.

In an embodiment of the present inventive concept, the depletion region may be formed by the first and second gate semiconductor layers 371 and 372. For example, a first depletion region DPR1 may be formed in the second channel pattern 352 by the first gate semiconductor layer 371, and a second depletion region DPR2 may be formed in the third channel pattern 353 by the second gate semiconductor layer 372. The first and second depletion regions DPR1 and DPR2 may represent a region in which the flow of the two-dimensional electron gas 134 is disconnected in the first and second drift regions DTR1 and DTR2. When the first depletion region DPR1 is generated, no current may flow between the sub-source electrode 173s and the third connection wire 413 and the channel path may be blocked. When the second depletion region DPR2 is generated, no current may flow between the fourth connection wire 414 and the sub-source electrode 173s, and the channel path may be blocked. Hence, the transistors of the inverter circuits 321 and 322 of the semiconductor device according to an embodiment of the present inventive concept may have the normally-off characteristic.

The sub-source electrode 173s may be disposed on one sides of the second and third channel patterns 352 and 353. The sub-source electrode 173s may contact the second and third channel patterns 352 and 353, and may be electrically connected to the second and third channel patterns 352 and 353. The sub-source electrode 173s may be disposed outside the second drift regions DTR1 and DTR2. Other descriptions of the sub-source electrode 173s substantially correspond to those of the sub-source electrode 173s given with FIG. 9 so they will be omitted.

The third connection wire 413 electrically connect the second channel pattern 352 and the second gate electrode 362 to each other. The third connection wire 413 may penetrate the first protection layer 140 and the barrier layer 136 and may be electrically connected to the second channel pattern 352, and may be electrically connected to the second gate electrode 362 through the fifth contact via CT5 that penetrates the first protection layer 140. The third connection wire 413 may overlap the second gate electrode 362 in the vertical direction (e.g., the thickness direction of the channel layer 132). At least a portion of the third connection wire 413 may overlap the separation structure 160 in the vertical direction (e.g., the thickness direction of the channel layer 132), but the present inventive concept is not limited thereto.

The third connection wire 413 may contact the second channel pattern 352, and may be electrically connected to the second channel pattern 352. The third connection wire 413 may be disposed outside the first drift region DTR1 and the third drift resistance region DTR_r3. The third connection wire 413 may be disposed between the fifth connection wire 415 and the sub-source electrode 173s. In an embodiment of the present inventive concept, the third connection wire 413 may be disposed in a space in which at least a portion of the second channel pattern 352 is recessed. The third connection wire 413 may penetrate the barrier layer 136 and may contact the lateral surface of the second channel pattern 352. The third connection wire 413 may be electrically connected to the first drift region DTR1 and the third drift resistance region DTR_r3.

The fourth connection wire 414 electrically connect the third channel pattern 353 and the third gate electrode 363, which is to be described later, to each other. The fourth connection wire 414 may penetrate the first protection layer 140 and the barrier layer 136 and may be electrically connected to the third channel pattern 353. The fourth connection wire 414 may be electrically connected to the third gate electrode 363 through a seventh contact via CT7 that penetrates the first protection layer 140. The fourth connection wire 414 may overlap the third gate electrode 363 in the vertical direction (e.g., the thickness direction of the channel layer 132). At least a portion of the fourth connection wire 414 may overlap the separation structure 160 in the vertical direction (e.g., the thickness direction of the channel layer 132), but the present inventive concept is not limited thereto.

The fourth connection wire 414 may contact the third channel pattern 353, and may be electrically connected to the third channel pattern 353. The fourth connection wire 414 may be disposed outside the second drift region DTR2 and the fourth drift resistance region DTR_r4. In an embodiment of the present inventive concept, the fourth connection wire 414 may be disposed in a space in which at least a portion of the third channel pattern 353 is recessed. The fourth connection wire 414 may penetrate the barrier layer 136 and may contact the lateral surface of the third channel pattern 353. The fourth connection wire 414 may be electrically connected to the second drift region DTR2 and the fourth drift resistance region DTR_r4.

The fifth connection wire 415 electrically connect the second channel pattern 352 and the third channel pattern 353 to each other. The fifth connection wire 415 may contact the second channel pattern 352 and the third channel pattern 353. In an embodiment of the present inventive concept, the fifth connection wire 415 may be disposed in a space in which at least a portion of the third channel pattern 353 is recessed. The fifth connection wire 415 may penetrate the barrier layer 136 and may contact the lateral surface of the third channel pattern 353. At least a portion of the fifth connection wire 415 may overlap the separation structure 160 in the vertical direction (e.g., the thickness direction of the channel layer 132), but the present inventive concept is not limited thereto. The fifth connection wire 415 may be disposed outside the third drift resistance region DTR_r3 and the fourth drift resistance region DTR_r4. The fifth connection wire 415 may be electrically connected to the third drift resistance region DTR_r3 and the fourth drift resistance region DTR_r4.

The fifth connection wire 415 may be disposed on the other side of the second channel pattern 352 and the other side of the third channel pattern 353. For example, the fifth connection wire 415 may be disposed between the second channel pattern 352 and the third channel pattern 353. For example, the sub-source electrode 173s may be disposed on one sides of the second channel pattern 352 and the third channel pattern 353, and the fifth connection wire 415 may be disposed on the other sides of the second channel pattern 352 and the third channel pattern 353. For example, the third connection wire 413 may be disposed between the fifth connection wire 415 and the sub-source electrode 173s on the second channel pattern 352, and the fourth connection wire 414 may be disposed between the fifth connection wire 415 and the sub-source electrode 173s on the third channel pattern 353.

The third to fifth connection wires 413, 414, and 415 may include a conductive material. The third to fifth connection wires 413, 414, and 415 may include the same material as the first and second connection wires 411 and 412. The third to fifth connection wires 413, 414, and 415 may include the same material, but the present inventive concept is not limited thereto. The third to fifth connection wires 413, 414, and 415 may substantially include the same material as the sub-source electrode 173s and/or the gate electrode 155, but the present inventive concept is not limited thereto. For example, the third to fifth connection wires 413, 414, and 415 may include a metal, a metal alloy, a conductive metal nitride, a metal silicide, a doped semiconductor material, a conductive metal oxide, or a conductive metal oxynitride.

A first transistor of the semiconductor device according to an embodiment of the present inventive concept will now be described with reference to FIG. 6 and FIG. 11.

Referring to FIG. 6 and FIG. 11, the first transistor Q1 of the semiconductor device according to an embodiment of the present inventive concept may include a fourth channel pattern 354, a barrier layer 136 disposed on the fourth channel pattern 354, a third gate electrode 363 disposed on the barrier layer 136, a third gate semiconductor layer 373 disposed between the barrier layer 136 and the third gate electrode 363, a first protection layer 140 disposed on the barrier layer 136, a sub-source electrode 173s, and a first connection wire 411 spaced apart from the sub-source electrode 173s on the fourth channel pattern 354.

The fourth channel pattern 354 may be disposed on the substrate 110. The fourth channel pattern 354 represents a layer for forming a channel between the sub-source electrode 173s and the first connection wire 411, and the two-dimensional electron gas (2DEG) 134 may be disposed in the fourth channel pattern 354. The two-dimensional electron gas 134 may be generated at the interface between the fourth channel pattern 354 and the barrier layer 136 in the semiconductor device according to an embodiment of the present inventive concept. For example, the two-dimensional electron gas 134 may be generated near the barrier layer 136 in the fourth channel pattern 354. In an embodiment of the present inventive concept, the fourth channel pattern 354 may be disposed in the peripheral circuit area PA, and may configure the channel region of the first transistor Q1.

The fourth channel pattern 354 may be spaced apart from the first to third channel patterns 351, 352, and 353. For example, the fourth channel pattern 354 may be spaced from the first to third channel patterns 351, 352, and 353 in the second direction (Y direction). A separation structure 160 may be disposed between the fourth channel pattern 354 and the third channel pattern 353. The fourth channel pattern 354 may be separated from the third channel pattern 353 by the separation structure 160.

In an embodiment of the present inventive concept, the fourth channel pattern 354 may be integrally formed with the channel layer 132 of the high electron mobility transistor HQ and the first to third channel patterns 351, 352, and 353 by the same process. Other descriptions of the fourth channel pattern 354 substantially correspond to those of the second channel pattern 352 and the third channel pattern 353 so they will be omitted.

The barrier layer 136 may be disposed on the fourth channel pattern 354. For example, the barrier layer 136 may be disposed on the fourth channel pattern 354. Without being limited to this, another predetermined layer may be disposed between the fourth channel pattern 354 and the barrier layer 136. A region of the fourth channel pattern 354 overlapping the barrier layer 136 may be a drift region.

As shown in FIG. 11, the fourth channel pattern 354 may include a third drift region DTR3. For example, the fourth channel pattern 354 may include a third drift region DTR3 extending from one side of the fourth channel pattern 354, which contacts the sub-source electrode 173s, to another side of the fourth channel pattern 354, which contacts the first connection wire 411. The third drift region DTR3 may represent a region in which the carriers move in the fourth channel pattern 354. In an embodiment of the present inventive concept, the third drift region DTR3 may extend in the first direction (X direction), but the present inventive concept is not limited thereto.

In an embodiment of the present inventive concept, the first transistor Q1 may be turned on/off according to the voltage applied to the third gate electrode 363, and the movement of the carriers may be allowed or blocked in the third drift region DTR3.

The third gate electrode 363 may be disposed on the barrier layer 136. For example, the third gate electrode 363 may be disposed on a portion of the barrier layer 136 that is disposed on the fourth channel pattern 354. The third gate electrode 363 may overlap the fourth channel pattern 354 in the third direction (Z direction). The third gate electrode 363 may overlap a portion of the third drift region DTR3 in the third direction (Z direction).

The third gate electrode 363 may be spaced apart from the first and second gate electrodes 361 and 362. For example, the third gate electrode 363 may be spaced from the first and second gate electrodes 361 and 362 in the second direction (Y direction), but the present inventive concept is not limited thereto. Other descriptions of the third gate electrode 363 substantially correspond to those of the gate electrode 155 given according to the embodiment of FIG. 7 and FIG. 8 so they will be omitted.

The third gate electrode 363 may include a conductive material. The third gate electrode 363 may include the same material as the gate electrode 155 of the high electron mobility transistor HQ. The third gate electrode 363 may include the same material as the first and second gate electrodes 361 and 362, but the present inventive concept is not limited thereto. For example, the third gate electrode 363 may include a metal, a metal alloy, a conductive metal nitride, a metal silicide, a doped semiconductor material, a conductive metal oxide, or a conductive metal oxynitride.

The third gate semiconductor layer 373 may be disposed between the barrier layer 136 and the third gate electrode 363. That is, the third gate semiconductor layer 373 may be disposed on the barrier layer 136, and the third gate electrode 363 may be disposed on the third gate semiconductor layer 373. The third gate electrode 363 may Schottky contact or ohmic contact the third gate semiconductor layer 373. The third gate semiconductor layer 373 may include the same material as the gate semiconductor layer 152 of the high electron mobility transistor HQ. The third gate semiconductor layer 373 may include the same material as the first and second gate semiconductor layers 371 and 372, but the present inventive concept is not limited thereto. For example, the third gate semiconductor layer 373 may include one or more materials of the Group III-V materials, for example, nitrides containing Al, Ga, In, B, or combinations thereof.

In an embodiment of the present inventive concept, a depletion region may be formed by the third gate semiconductor layer 373. For example, a third depletion region DPR3 may be formed in the fourth channel pattern 354 by the third gate semiconductor layer 373. The third depletion region DPR3 may represent a region in which the flow of the two-dimensional electron gas 134 is disconnected in the third drift region DTR3. As the third depletion region DPR3 is generated, no current may flow between the sub-source electrode 173s and the first connection wire 411, and the channel path may be blocked. Hence, the first transistor Q1 of the semiconductor device according to an embodiment of the present inventive concept may have the normally off characteristic.

The sub-source electrode 173s may be disposed on one side of the fourth channel pattern 354. The sub-source electrode 173s may contact the fourth channel pattern 354, and may be electrically connected to the fourth channel pattern 354. The sub-source electrode 173s may be disposed outside the third drift resistance regions DTR3. Other descriptions of the sub-source electrode 173s substantially correspond to those of the sub-source electrode 173s given according to the embodiment of FIG. 9 so they will be omitted.

The first connection wire 411 electrically connect the fourth channel pattern 354, the gate electrode 155 of the high electron mobility transistor HQ, and the first channel pattern 351 to each other. The first connection wire 411 may be electrically connected to the gate electrode 155 through the first contact via CT1 that penetrates the first protection layer 140, and may be electrically connected to the first channel pattern 351 by penetrating the first protection layer 140 and the barrier layer 136. The first connection wire 411 may be electrically connected to the fourth channel pattern 354 by penetrating the first protection layer 140 and the barrier layer 136. The first connection wire 411 may overlap the fourth channel pattern 354 in the third direction (Z direction). At least a portion of the first connection wire 411 may overlap the separation structure 160 in the vertical direction (e.g., the thickness direction of the channel layer 132), but the present inventive concept is not limited thereto.

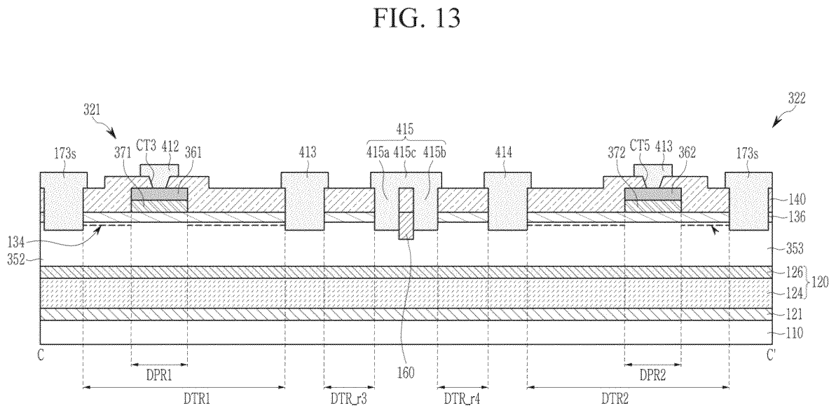

A semiconductor device according to embodiments of the present inventive concept will now be described with reference to FIG. 13.

FIG. 13 shows a cross-sectional view on a semiconductor device according to embodiments of the present inventive concept, corresponding to C-C′ of FIG. 6.

Referring to FIG. 13, the fifth connection wire 415 of the semiconductor device according to embodiments of the present inventive concept may electrically connect the second channel pattern 352 and the third channel pattern 353 to each other.

In embodiments of the present inventive concept, the fifth connection wire 415 may include a first portion 415a disposed on the second channel pattern 352, a second portion 415b disposed on the third channel pattern 353, and a third portion 415c connecting the first portion 415a and the second portion 415b to each other. The first portion 415a may penetrate the first protection layer 140 and the barrier layer 136 and may contact the second channel pattern 352. The second portion 415b may penetrate the first protection layer 140 and the barrier layer 136 and may contact the third channel pattern 353. The third portion 415c may be disposed on the first protection layer 140. The third portion 415c may be disposed directly on the first protection layer 140 to connect the first portion 415a and the second portion 415b protruding from the upper surface of the first protection layer 140. For example, the third portion 415c may be disposed on an upper surface of the first protection layer 140. The separation structure 160 may be disposed below the third portion 415c. For example, the third portion 415c may overlap the separation structure 160 in the third direction (Z direction).

A semiconductor device according to embodiments of the present inventive concept will now be described with reference to FIG. 14 to FIG. 16.

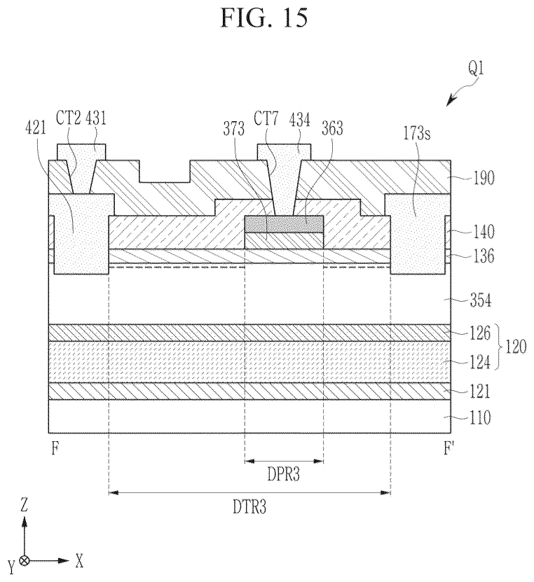

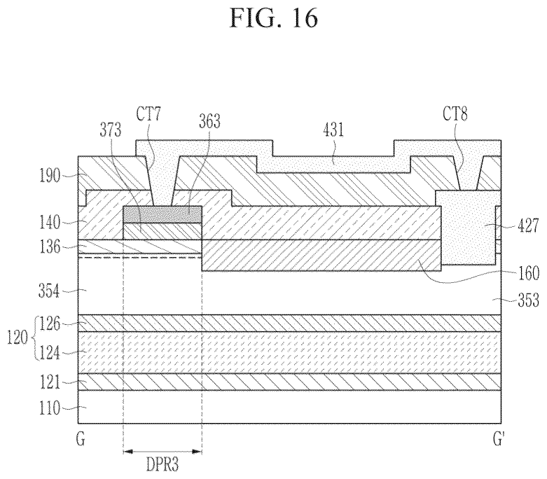

FIG. 14 shows a top plan view on a semiconductor device according to embodiments of the present inventive concept. FIG. 15 shows a cross-sectional view with respect to a line F-F′ of FIG. 14. FIG. 16 shows a cross-sectional view with respect to a line G-G′ of FIG. 14.

Referring to FIG. 14 to FIG. 16, connection wires of the semiconductor device according to embodiments of the present inventive concept may have various arrangements and shapes. The semiconductor device may include lower electrodes 421 to 427 disposed on the channel patterns 351 to 354, a second protection layer 190 for covering the lower electrodes 421 to 427 and the first protection layer 140, and upper connection wires 431 to 435 disposed on the second protection layer 190. In embodiments of the present inventive concept, the lower electrodes 421 to 427 may be disposed on the same layer as the main source electrode 173m, the main drain electrode 175, and the sub-source electrode 173s. For example, a thickness of the lower electrodes 421 to 427 in the third direction (Z direction) may be substantially the same as the thickness of the sub-source electrode 173s in the third direction (Z direction). In another way, lower surfaces of the lower electrodes 421 to 427 may be disposed on substantially the same level as the lower surface of the sub-source electrode 173s. For example, a distance between the lower surfaces of the lower electrodes 421 to 427 and the upper surface of the substrate 110 may be substantially the same as the distance between the lower surface of the sub-source electrode 173s and the upper surface of the substrate 110. The lower electrodes 421 to 427 may be simultaneously formed with the sub-source electrode 173s by the same process.

The resisting elements 311 and 312 of the semiconductor device according to embodiments of the present inventive concept may include a second lower electrode 422 and a third lower electrode 423 contacting the first channel pattern 351. The second lower electrode 422 may be disposed on one side of the first channel pattern 351. The third lower electrode 423 may be disposed between the second lower electrode 422 and the sub-source electrode 173s. The second lower electrode 422 and the third lower electrode 423 may contact the first channel pattern 351.

The first upper connection wire 431 may electrically connect the gate electrode 155 of the high electron mobility transistor HQ and the second lower electrode 422. The first upper connection wire 431 may be electrically connected to the gate electrode 155 through the first contact via CT1 that penetrates the second protection layer 190 and the first protection layer 140, and may penetrate the second protection layer 190. The first upper connection wire 431 may be electrically connected to the second lower electrode 422. The first upper connection wire 431 may overlap the gate electrode 155 and the second lower electrode 422 in the third direction (Z direction). At least a portion of the first upper connection wire 431 may overlap the separation structure 160 in the third direction (Z direction), but the present inventive concept is not limited thereto. In embodiments of the present inventive concept, the first upper connection wire 431 may be connected to the first lower electrode 421 through a second contact via CT2 penetrating the second protection layer 190.

The inverter circuits 321 and 322 of the semiconductor device according to embodiments of the present inventive concept may include a fourth lower electrode 424 and a fifth lower electrode 425 disposed on the second channel pattern 352, and a sixth lower electrode 426 and a seventh lower electrode 427 disposed on the third channel pattern 353.

The fifth lower electrode 425 may be disposed on one side of the second channel pattern 352. The fourth lower electrode 424 may be disposed between the fifth lower electrode 425 and the sub-source electrode 173s. The fourth lower electrode 424 and the fifth lower electrode 425 may contact the second channel pattern 352.

The sixth lower electrode 426 may be disposed on one side of the third channel pattern 353. The seventh lower electrode 427 may be disposed between the sixth lower electrode 426 and the sub-source electrode 173s. The sixth lower electrode 426 and the seventh lower electrode 427 may contact the third channel pattern 353. In embodiments of the present inventive concept, they may further include a second upper connection wire 432 for connecting the third lower electrode 423 and the first gate electrode 361 to each other, a third upper connection wire 433 for connecting the fourth lower electrode 424 and the second gate electrode 362 to each other, and a fifth upper connection wire 435 for connecting the fifth lower electrode 425 and the sixth lower electrode 426 to each other.

The second upper connection wire 432 electrically connect the third lower electrode 423 and the first gate electrode 361 to each other. The second upper connection wire 432 may be electrically connected to the first gate electrode 361 through a third contact via CT3 that penetrates the second protection layer 190 and the first protection layer 140, and may be electrically connected to the third lower electrode 423 through a fourth contact via CT4 that penetrates the second protection layer 190. The second upper connection wire 432 may overlap the first gate electrode 361 and the third lower electrode 423 in the third direction (Z direction). At least a portion of the second upper connection wire 432 may overlap the separation structure 160 in the third direction (Z direction), but present inventive concept is not limited thereto.

The third upper connection wire 433 may electrically connect the fourth lower electrode 424 and the second gate electrode 362 to each other. The third upper connection wire 433 may be electrically connected to the second gate electrode 362 through a fifth contact via CT5 that penetrates the second protection layer 190 and the first protection layer 140, and may be electrically connected to the fourth lower electrode 424 through a sixth contact via CT6 that penetrates the second protection layer 190. The third upper connection wire 433 may overlap the second gate electrode 362 and the fourth lower electrode 424 in the third direction (Z direction). At least a portion of the third upper connection wire 433 may overlap the separation structure 160 in the third direction (Z direction), but the present inventive concept is not limited thereto.

The fifth upper connection wire 435 may electrically connect the fifth lower electrode 425 and the sixth lower electrode 426 to each other. The second upper connection wire 432 may penetrate the second protection layer 190 and may be electrically connected to the fifth lower electrode 425 and the sixth lower electrode 426. The fifth upper connection wire 435 may overlap the fifth lower electrode 425 and the sixth lower electrode 426 in the third direction (Z direction). At least a portion of the fifth upper connection wire 435 may overlap the separation structure 160 in the third direction (Z direction), but the present inventive concept is not limited thereto.

The first transistor Q1 of the semiconductor device according to embodiments of the present inventive concept may include a first lower electrode 421 contacting the fourth channel pattern 354. The first lower electrode 421 may be disposed on one side of the fourth channel pattern 354.

In embodiments of the present inventive concept, the fourth upper connection wire 434 may electrically connect the first lower electrode 421 and the third gate electrode 363 to each other. The fourth upper connection wire 434 may be electrically connected to the third gate electrode 363 through a seventh contact via CT7 that penetrates the second protection layer 190 and the first protection layer 140, and may be electrically connected to the seventh lower electrode 427 through an eighth contact via CT8 penetrating the second protection layer 190. The fourth upper connection wire 434 may overlap the third gate electrode 363 and the seventh lower electrode 427 in the third direction (Z direction). At least a portion of the fourth upper connection wire 434 may overlap the separation structure 160 in the third direction (Z direction), but the present inventive concept is not limited thereto.

The lower electrodes 421 to 427 and the upper connection wires 431 to 435 may include conductive materials. The lower electrodes 421 to 427 may include substantially the same material as the sub-source electrode 173s and/or the gate electrode 155, but the present inventive concept is not limited thereto. The upper connection wires 431 to 435 may include the same material as the lower electrodes 421 to 427, but present inventive concept not limited thereto. For example, the upper connection wires 431 to 435 may include different materials from the lower electrodes 421 to 427. For example, the lower electrodes 421 to 427 and the upper connection wires 431 to 435 may include a metal, a metal alloy, a conductive metal nitride, a metal silicide, a doped semiconductor material, a conductive metal oxide, or a conductive metal oxynitride.

A semiconductor device according to embodiments of the present inventive concept will now be described with reference to FIG. 17 to FIG. 21.

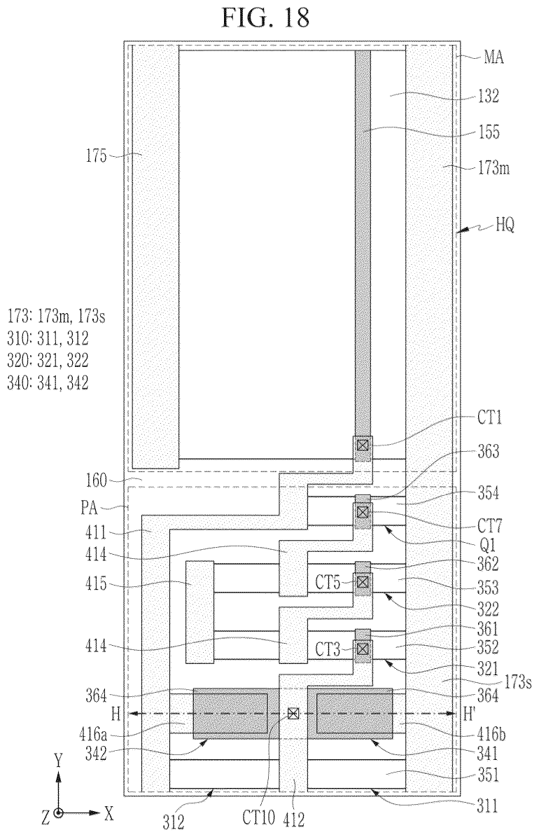

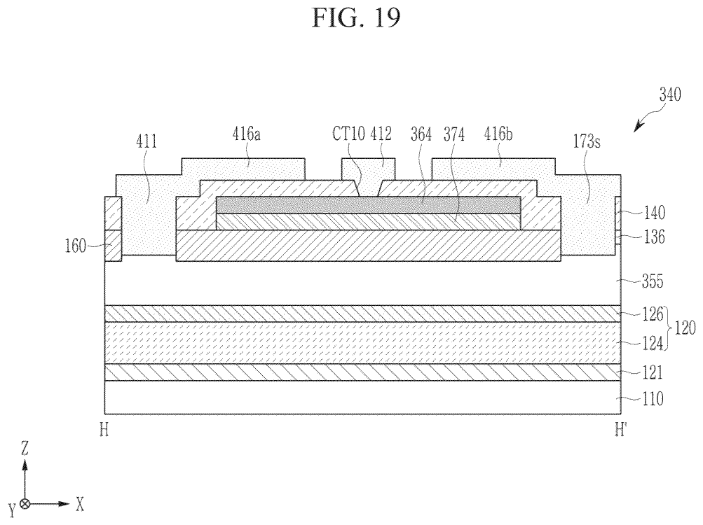

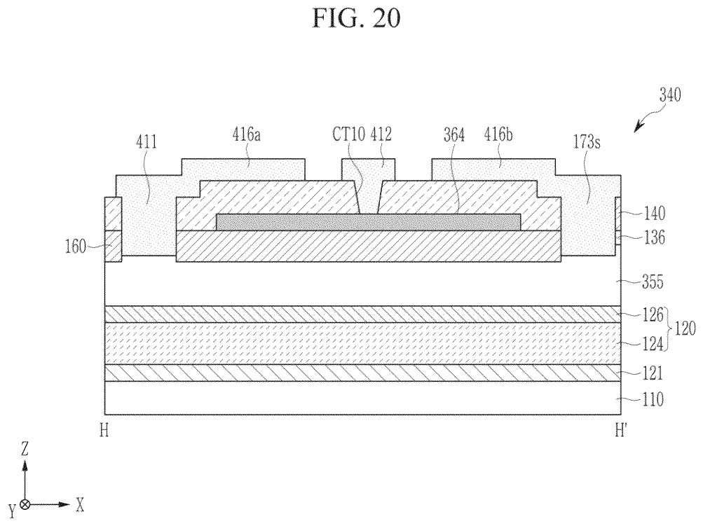

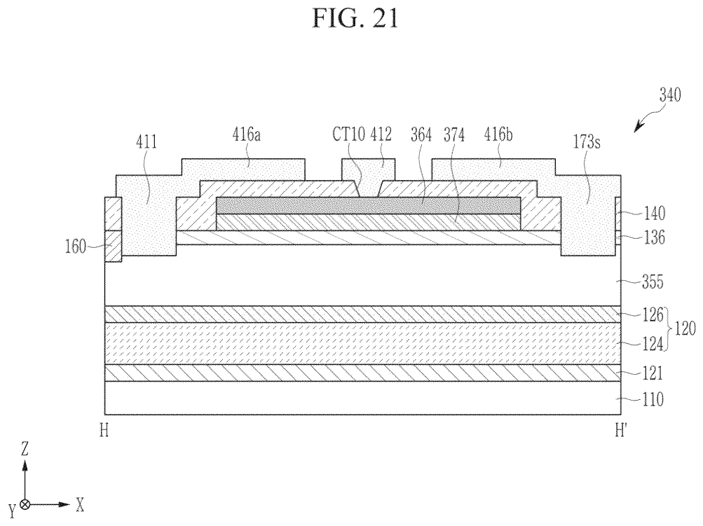

FIG. 17 shows a circuit diagram on a semiconductor device according to embodiments of the present inventive concept. FIG. 18 shows a top plan view on a semiconductor device according to an embodiment of FIG. 17. FIG. 19 shows a cross-sectional view with respect to a line H-H′ of FIG. 18. FIG. 20 and FIG. 21 show cross-sectional views on a semiconductor device according to embodiments of the present inventive concept, corresponding to H-H′ of FIG. 18.

Referring to FIG. 17, the voltage dividing circuit 310 of the semiconductor device according to embodiments of the present inventive concept may further include capacitors C1 and C2 coupled in series between the first node N1 and the second node N2. Hence, the voltage divided by an impedance ratio of the resistors R1 and R2 and the capacitors C1 and C2 may be output to the third node N3. In embodiments of the present inventive concept, when an excessive voltage is applied to the first node N1, the capacitors C1 and C2 may store at least a portion of the voltage applied to the first node N1, thereby preventing the excessive voltage from being applied to the gate G of the high electron mobility transistor HQ.

Referring to FIG. 18 to FIG. 21, the semiconductor device according to embodiments of the present inventive concept may further include capacitor elements 341 and 342. The capacitor elements 341 and 342 may correspond to capacitors C1 and C2 according to an embodiment of FIG. 17.

The capacitor elements 341 and 342 may include a fifth channel pattern 355, a fourth gate electrode 364 disposed on the fifth channel pattern 355, a first protection layer 140 covering the fourth gate electrode 364, and sub-electrodes 416a and 416b disposed on the first protection layer 140. The capacitor elements 341 and 342 according to an embodiment of FIG. 18 to FIG. 21 may be configured with the capacitors C1 and C2 according to an embodiment of FIG. 17. For example, the first capacitor element 341 may be configured with the first capacitor C1 according to an embodiment of FIG. 17. The first electrode of the first capacitor C1 may correspond to the first sub-electrode 416a, and the second electrode may correspond to the fourth gate electrode 364. The second capacitor element 342 may be configured with the second capacitor C2 according to an embodiment of FIG. 17. A first electrode of the second capacitor C2 may correspond to the fourth gate electrode 364, and a second electrode may correspond to the second sub-electrode 416b.

The fifth channel pattern 355 may be disposed on the substrate 110. The fifth channel pattern 355 may be spaced apart from the first to fourth channel patterns 351, 352, 353, and 354. For example, the fifth channel pattern 355 may be spaced apart from the first to fourth channel patterns 351, 352, 353, and 354 in the second direction (Y direction). For example, the fifth channel pattern 355 may be disposed between the first channel pattern 351 and the second channel pattern 352, but present inventive concept is not limited thereto. The separation structure 160 may be disposed between the fifth channel pattern 355 and the first channel pattern 351 and between the fifth channel pattern 355 and the second channel pattern 352. The fifth channel pattern 355 may be separated from the first to fourth channel patterns 351, 352, 353, and 354 by the separation structure 160.

The fourth gate electrode 364 may be disposed on the fifth channel pattern 355. The fourth gate electrode 364 may be disposed between the sub-source electrode 173s and the first connection wire 411. The fourth gate electrode 364 may be spaced apart from the sub-source electrode 173s and the first connection wire 411. For example, the fourth gate electrode 364 may be spaced apart from the sub-source electrode 173s and the first connection wire 411 in the first direction (X direction), but the present inventive concept is not limited thereto. The fourth gate electrode 364 may be disposed on the fifth channel pattern 355 and/or the separation structure 160, but the present inventive concept is not limited thereto.

In embodiments of the present inventive concept, various layers may be disposed between the fourth gate electrode 364 and the fifth channel pattern 355. For example, as shown in FIG. 19, the separation structure 160, which is disposed on the fifth channel pattern 355, and the fourth gate semiconductor layer 374, which is disposed between the separation structure 160 and the fourth gate electrode 364, may be included. For another example, as shown in FIG. 20, the fourth gate semiconductor layer, which is disposed between the separation structure 160 and the fourth gate electrode 364, may be omitted. For another example, as shown in FIG. 21, the separation structure 160 might not be disposed on the fifth channel pattern 355. Here, the barrier layer 136 may be disposed on the fifth channel pattern 355, and the fourth gate semiconductor layer 374 may be disposed on the barrier layer 136.

The first protection layer 140 may cover the fourth gate electrode 364. The first protection layer 140 may cover the upper surface and the lateral surface of the fourth gate electrode 364. The first protection layer 140 may be disposed between the fourth gate electrode 364 and the first connection wire 411 and between the fourth gate electrode 364 and the sub-source electrode 173s. The lower surface of the first protection layer 140 may contact the separation structure 160 or the barrier layer 136. Hence, the fourth gate electrode 364 may be protected by the first protection layer 140. The first protection layer 140 may include an insulating material. For example, the first protection layer 140 may include an oxide such as SiO₂ or Al₂O₃. For another example, the first protection layer 140 may include a nitride such as SiN or an oxynitride such as SiON.

FIG. 19 to FIG. 21 show that the first protection layer 140 is a single layer, but without being limited thereto, the first protection layer 140 may be a multilayer including different materials.

The first sub-electrode 416a and the second sub-electrode 416b may be disposed on the first protection layer 140. The first sub-electrode 416a and the second sub-electrode 416b may overlap the fourth gate electrode 364 in the third direction (Z direction). For example, the first protection layer 140 may be disposed between the first sub-electrode 416a and the fourth gate electrode 364 and between the second sub-electrode 416b and the fourth gate electrode 364.

The first sub-electrode 416a may be connected to the first connection wire 411. The first sub-electrode 416a may be integrally formed with first connection wire 411, but the present inventive concept is not limited thereto. The second sub-electrode 416b may be connected to the sub-source electrode 173s. For example, the second sub-electrode 416b may be integrally formed with the sub-source electrode 173s, but the present inventive concept is not limited thereto. The first sub-electrode 416a may be spaced apart from the second sub-electrode 416b. For example, the first sub-electrode 416a may be spaced the present inventive concept from the second sub-electrode 416b in the first direction (X direction). Hence, the first sub-electrode 416a, the fourth gate electrode 364, and the first protection layer 140 disposed between the first sub-electrode 416a and the fourth gate electrode 364 may function as the first capacitor C1 according to an embodiment of FIG. 17. The second sub-electrode 416b, the fourth gate electrode 364, and the first protection layer 140 disposed between the second sub-electrode 416b and the fourth gate electrode 364 may function as the second capacitor C2 according to an embodiment of FIG. 17.

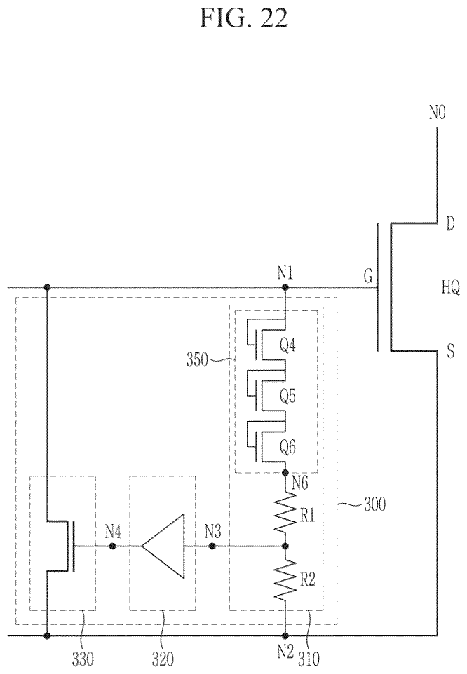

A semiconductor device according to embodiments of the present inventive concept will now be described with reference to FIG. 22 to FIG. 25.

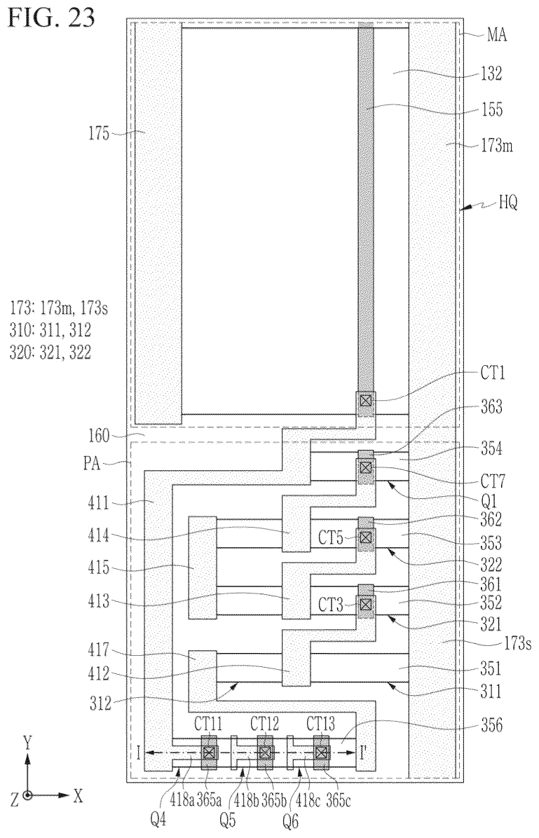

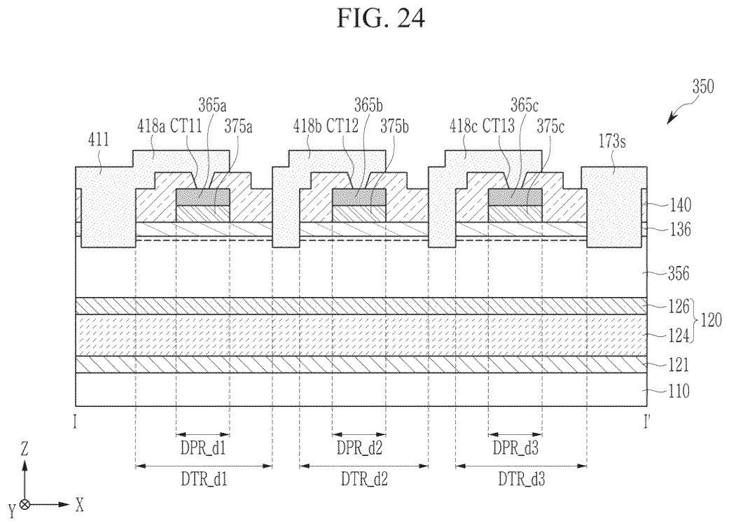

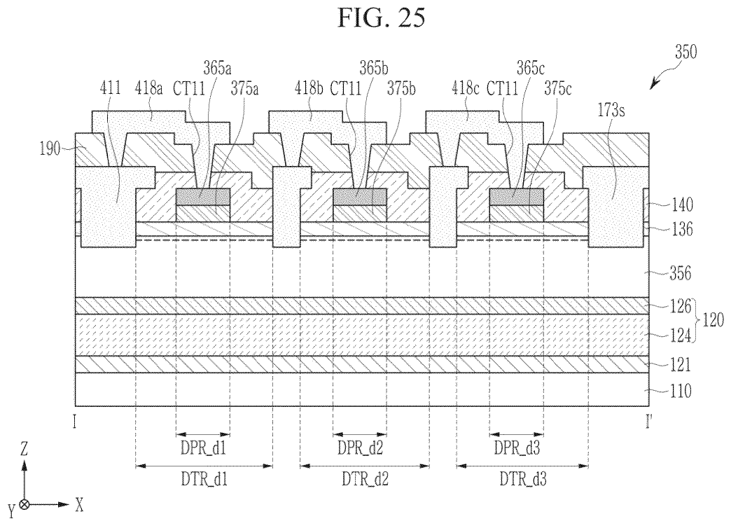

FIG. 22 shows a circuit diagram on a semiconductor device according to embodiments of the present inventive concept. FIG. 23 shows a top plan view on a semiconductor device according to an embodiment of FIG. 22. FIG. 24 shows a cross-sectional view with respect to a line I-I′ of FIG. 23. FIG. 25 shows a cross-sectional view on a semiconductor device according to embodiments of the present inventive concept, corresponding to I-I′ of FIG. 23.

Referring to FIG. 22, the voltage dividing circuit 310 of the semiconductor device according to embodiments of the present inventive concept may further include a diode element 350 that is connected between the first node N1 and the resistors R1 and R2. The diode element 350 may be connected between the first node N1 and the sixth node N6, and the resistors R1 and R2 may be connected between the sixth node N6 and the second node N2.

The diode element 350 may include transistors Q4, Q5, and Q6. In detail, the diode element 350 may include the fourth transistor Q4 that is connected between the first node N1 and the sixth node N6 and including a gate that is connected to the first node N1. The diode element 350 may also include the fifth transistor Q5 that is connected between the fourth transistor Q4 and the sixth node N6 and including a gate that is connected to one end of the fourth transistor Q4, and the sixth transistor Q6 that is connected between the fifth transistor Q5 and the sixth node N6 and including a gate that is connected to one end of the fifth transistor Q5. The diode element 350 may cancel the connection between the first node N1 and the sixth node N6 when a voltage that is less than a sum of the threshold voltages of the fourth to sixth transistors Q4 to Q6 is input to the first node N1. The diode element 350 may output the voltage input to the first node N1 to the sixth node N6 when the voltage that is equal to or greater than the sum of the threshold voltages of the fourth to sixth transistors Q4 to Q6 is input to the first node N1. Hence, the diode element 350 may prevent a current path from being formed in the electrostatic discharge protection circuit 300 when the voltage that is less than the sum of the threshold voltages of the fourth to sixth transistors Q4 to Q6 is input to the first node N1. The diode element 350 may function so that the electrostatic discharge protection circuit 300 according to an embodiment of FIG. 1 to FIG. 21 when the voltage that is equal to or greater than the threshold voltages of the fourth to sixth transistors Q4 to Q6 is input to the first node N1.

Referring to FIG. 23 to FIG. 25, the semiconductor device according to embodiments of the present inventive concept may further include the transistors Q4 to Q6. The transistors Q4 to Q6 may correspond to the transistors Q4 to Q6 of the diode element 350 according to an embodiment of FIG. 22.

The transistors Q4 to Q6 of the semiconductor device according to embodiments of the present inventive concept may include a sixth channel pattern 356, a barrier layer 136 disposed on the sixth channel pattern 356, first to third sub-gate electrodes 365a, 365b, and 365c disposed on the barrier layer 136, first to third sub-gate semiconductor layers 375a, 375b, and 375c disposed between the barrier layer 136 and the first to third sub-gate electrodes 365a, 365b, and 365c, a first protection layer 140 for covering the first to third sub-gate electrodes 365a, 365b, and 365c, and first to third sub-connection electrodes 418a, 418b, and 418c for connecting the first to third sub-gate electrodes 365a, 365b, and 365c and the sixth channel pattern 356. The transistors Q4 to Q6 according to an embodiment of FIG. 23 to FIG. 25 may be configured with the transistors Q4 to Q6 according to an embodiment of FIG. 22. For example, a source of the fourth transistor Q4 may correspond to the second sub-connection electrode 418b, and a drain of the fourth transistor Q4 may correspond to the first connection wire 411. A gate of the fourth transistor Q4 may correspond to the first sub-gate electrode 365a. A source of the fifth transistor Q5 may correspond to the third sub-connection electrode 418c, and a drain of the fifth transistor Q5 may correspond to the second sub-connection electrode 418b. A gate of the fifth transistor Q5 may correspond to the second sub-gate electrode 365b. A source of the sixth transistor Q6 may correspond to the sub-source electrode 173s, and a drain of the sixth transistor Q6 may correspond to the third sub-connection electrode 418c. A gate of the sixth transistor Q6 may correspond to the third sub-gate electrode 365c.

The sixth channel pattern 356 may be disposed on the substrate 110. The sixth channel pattern 356 may be a layer for forming a channel between the first connection wire 411 and the second sub-connection wire 418b, between the second sub-connection wire 418b and the third sub-connection wire 418c, and between the third sub-connection wire 418c and the sub-source electrode 173s, and two-dimensional electron gas (2DEG) 134 may be disposed in the sixth channel pattern 356. The two-dimensional electron gas 134 may be generated at the interface between the sixth channel pattern 356 and the barrier layer 136 in the semiconductor device according to an embodiment of the present inventive concept.

The sixth channel pattern 356 may be spaced apart from the first to fourth channel patterns 351, 352, 353, and 354. For example, the sixth channel pattern 356 may be spaced apart from the first to fourth channel patterns 351, 352, 353, and 354 in the second direction (Y direction). For example, the sixth channel pattern 356 may be disposed on one side of the first channel pattern 351 in the second direction (Y direction), but the present inventive concept is not limited thereto. The separation structure 160 may be disposed between the sixth channel pattern 356 and the first channel pattern 351. The sixth channel pattern 356 may be separated from the first to fourth channel patterns 351, 352, 353, and 354 by the separation structure 160.

In an embodiment of the present inventive concept, the sixth channel pattern 356 integrally formed with the channel layer 132 of the high electron mobility transistor HQ and the first to fourth channel patterns 351, 352, 353, and 354 by the same process. Other descriptions of the sixth channel pattern 356 substantially correspond to those of the first channel pattern 351 so they will be omitted.

The barrier layer 136 may be disposed on the sixth channel pattern 356. The region of the sixth channel pattern 356 overlapping the barrier layer 136 may be a drift region.

As shown in FIG. 24, the sixth channel pattern 356 may include sub-drift regions DTR_d1, DTR_d2, and DTR_d3. For example, the sixth channel pattern 356 may include a first sub-drift region DTR_d1 extending from one side of the sixth channel pattern 356, which contacts the first connection wire 411, to another side of the sixth channel pattern 356, which contacts the second sub-connection wire 418b. The sixth channel pattern 356 may further include a second sub-drift region DTR_d2 extending from one side of the sixth channel pattern 356, which contacts the second sub-connection wire 418b, to another side of the sixth channel pattern 356, which contacts the third sub-connection wire 418c, and a third sub-drift region DTR_d3 extending from one side of the sixth channel pattern 356, which contacts the third sub-connection wire 418c, to another side of the sixth channel pattern 356, which contacts the sub-source electrode 173s. The sub-drift regions DTR_d1, DTR_d2, and DTR_d3 may represent regions in which the carriers move in the sixth channel pattern 356. In an embodiment of the present inventive concept, the sub-drift regions DTR_d1, DTR_d2, and DTR_d3 may extend in the first direction (X direction), but the present inventive concept is not limited thereto.

In an embodiment of the present inventive concept, the fourth transistor Q4 may be turned on/off according to the voltage applied to the first sub-gate electrode 365a, the fifth transistor Q5 may be on/off according to the voltage applied to the second sub-gate electrode 365b, and the sixth transistor Q6 may be turned on/off according to the voltage applied to the third sub-gate electrode 365c. Hence, the movement of the carriers may be allowed or blocked in the sub-drift regions DTR_d1, DTR_d2, and DTR_d3.

The first to third sub-gate electrodes 365a, 365b, and 365c may be disposed on the barrier layer 136. The first to third sub-gate electrodes 365a, 365b, and 365c may overlap the sixth channel pattern 356 in the third direction (Z direction). The first sub-gate electrode 365a may overlap a portion of the first sub-drift region DTR_d1 in the third direction (Z direction). The second sub-gate electrode 365b may overlap a portion of the second sub-drift region DTR_d2 in the third direction (Z direction), and the third sub-gate electrode 365c may overlap a portion of the third sub-drift region DTR_d3 in the third direction (Z direction). Other descriptions of the first to third sub-gate electrodes 365a, 365b, and 365c substantially correspond to those of the gate electrode 155 given with the embodiment of FIG. 7 and FIG. 8, so they will be omitted.

The first to third sub-gate electrodes 365a, 365b, and 365c may be spaced apart from each other. For example, the first to third sub-gate electrodes 365a, 365b, and 365c may be spaced apart from each other in the first direction (X direction), but the present inventive concept is not limited thereto.

The first to third sub-gate electrodes 365a, 365b, and 365c may include a conductive material. Each of the first to third sub-gate electrodes 365a, 365b, and 365c may include the same material as the gate electrode 155 of the high electron mobility transistor HQ. The first to third sub-gate electrodes 365a, 365b, and 365c may include the same material, but the present inventive concept is not limited thereto. For example, each of the first to third sub-gate electrodes 365a, 365b, and 365c may include a metal, a metal alloy, a conductive metal nitride, a metal silicide, a doped semiconductor material, a conductive metal oxide, or a conductive metal oxynitride.

The first to third sub-gate semiconductor layers 375a, 375b, and 375c may be disposed between the barrier layer 136 and the first to third sub-gate electrodes 365a, 365b, and 365c. That is, the first to third sub-gate semiconductor layers 375a, 375b, and 375c may be disposed on the barrier layer 136, and the first to third sub-gate electrodes 365a, 365b, and 365c may be disposed on the first to third sub-gate semiconductor layers 375a, 375b, and 375c.

Each of the first to third sub-gate semiconductor layers 375a, 375b, and 375c may include the same material as the gate semiconductor layer 152 of the high electron mobility transistor HQ. The first to third sub-gate semiconductor layers 375a, 375b, and 375c and the second gate semiconductor layer 372 may include the same material, but the present inventive concept is not limited thereto. For example, the first to third sub-gate semiconductor layers 375a, 375b, and 375c may include one or more materials from the Group III-V materials, for example, nitrides containing Al, Ga, In, B, or combinations thereof.

In an embodiment of the present inventive concept, the depletion region may be formed by the first to third sub-gate semiconductor layers 375a, 375b, and 375c. For example, the sub-depletion regions DPR_d1, DPR_d2, and DPR_d3 may be formed in the sixth channel pattern 356 by the first to third sub-gate semiconductor layers 375a, 375b, and 375c. The sub-depletion regions DPR_d1, DPR_d2, and DPR_d3 may represent regions in which the flow of the two-dimensional electron gas 134 is disconnected in the sub-drift regions DTR_d1, DTR_d2, and DTR_d3. As the sub-depletion regions DPR_d1, DPR_d2, and DPR_d3 are generated, no current may flow between the sub-source electrode 173s and the first connection wire 411, and the channel path may be blocked. Hence, the fourth to sixth transistors Q4 to Q6 of the semiconductor device according to an embodiment the present inventive concept may have the normally off characteristic.

The first sub-connection wire 418a may connect the first sub-gate electrode 365a and the first connection wire 411 to each other. The first sub-connection wire 418a may be electrically connected to the first sub-gate electrode 365a through the eleventh contact via CT11 that penetrates the first protection layer 140, and may be electrically connected to the first connection wire 411. The first sub-connection wire 418a may be integrally formed with the first connection wire 411 by the same process, but the present inventive concept is not limited thereto. For example, as shown in FIG. 25, the first sub-connection wire 418a may be connected to the first connection wire 411 through the contact via that penetrates the second protection layer 190 that covers the first connection wire 411.

The second sub-connection wire 418b may connect the second sub-gate electrode 365b and the sixth channel pattern 356. The second sub-connection wire 418b may be electrically connected to the second sub-gate electrode 365b through the twelfth contact via CT12 that penetrates the first protection layer 140, and may penetrate the first protection layer 140 and the barrier layer 136. The second sub-connection wire 418b may be electrically connected to the sixth channel pattern 356. The second sub-connection wire 418b may contact the sixth channel pattern 356. The second sub-connection wire 418b may be disposed outside the first sub-drift region DTR_d1 and the second sub-drift region DTR_d2. The second sub-connection wire 418b may be electrically connected to the first sub-drift region DTR_d1 and the second sub-drift region DTR_d2.

The third sub-connection wire 418c may connect the third sub-gate electrode 365c and the sixth channel pattern 356 to each other. The third sub-connection wire 418c may be electrically connected to the third sub-gate electrode 365c through the thirteenth contact via CT13 that penetrates the first protection layer 140, and may penetrate the first protection layer 140 and the barrier layer 136. The third sub-connection wire 418c may be electrically connected to the sixth channel pattern 356. The third sub-connection wire 418c may contact the sixth channel pattern 356. The third sub-connection wire 418c may be disposed outside the second sub-drift region DTR_d2 and the third sub-drift region DTR_d3. The third sub-connection wire 418c may be electrically connected to the second sub-drift region DTR_d2 and the third sub-drift region DTR_d3.

The embodiment of FIG. 22 to FIG. 25 shows that the diode element 350 includes three transistors, but the number of the transistors may vary.

While the present inventive concept has been shown and described with reference to the embodiments thereof, it will be apparent to those of ordinary skill in the art that various changes in form and detail may be made thereto without departing from the spirit and scope of the present inventive concept.

### DESCRIPTION OF SYMBOLS

110: substrate
132: channel layer
134: two-dimensional electron gas
152: gate semiconductor layer
155: gate electrode
175: main drain electrode
173m: main source electrode
173s: sub-source electrode
300: electrostatic discharge protection circuit
310: voltage dividing circuit
320: digitizer circuit
330: protective circuit

What is claimed is:

1. A semiconductor device comprising:
a high electron mobility transistor;
a resisting element;
an inverter circuit connected to the resisting element; and
a first transistor,
wherein the high electron mobility transistor includes:
a channel layer;
a barrier layer disposed on the channel layer and including a material having a different energy band gap from that of the channel layer;
a gate electrode disposed on the barrier layer;
a gate semiconductor layer disposed between the barrier layer and the gate electrode; and
a main source electrode and a main drain electrode respectively disposed on opposite sides of the gate electrode and connected to the channel layer,
wherein the resisting element is connected between the gate electrode and the main source electrode, and
wherein the first transistor includes a gate that is connected between the main source electrode and the gate electrode and connected to the inverter circuit.

2. The semiconductor device of claim 1, wherein
the resisting element includes:
a first channel pattern disposed on one side of the channel layer;
a sub-source electrode disposed on the first channel pattern and connected to the main source electrode;
a first connection wire disposed on the first channel pattern and connected to the gate electrode; and
a second connection wire disposed between the sub-source electrode and the first connection wire and disposed on the first channel pattern,
wherein the inverter circuit is connected to the second connection wire.

3. The semiconductor device of claim 2, wherein
the barrier layer is disposed on the first channel pattern, and
the first connection wire penetrates the barrier layer and contacts the first channel pattern.

4. The semiconductor device of claim 2, wherein
the inverter circuit includes:
a first inverter circuit connected to the resisting element; and
a second inverter circuit for connecting the first inverter circuit and the first transistor to each other.

5. The semiconductor device of claim 4, wherein
the first inverter circuit includes:
a second channel pattern connected to the sub-source electrode;
a third connection wire disposed on the second channel pattern;
a second gate electrode disposed on the second channel pattern and connected to the second connection wire; and
a second gate semiconductor layer disposed between the second channel pattern and the second gate electrode, and
wherein the second inverter circuit includes:
the sub-source electrode and a third channel pattern;
a third gate electrode disposed on the third channel pattern and connected to the third connection wire; and
a third gate semiconductor layer disposed between the third channel pattern and the third gate electrode.

6. The semiconductor device of claim 5, wherein
at least a portion of the third connection wire overlaps the third gate electrode in a thickness direction of the third channel pattern.

7. The semiconductor device of claim 5, wherein
the second inverter circuit further includes
a fourth connection wire disposed on the third channel pattern and connected to a gate of the first transistor.

8. The semiconductor device of claim 7, wherein
the second gate electrode is disposed between the third connection wire and the sub-source electrode, and
the third gate electrode is disposed between the fourth connection wire and the sub-source electrode.

9. The semiconductor device of claim 5, further comprising
a fifth connection wire connecting the second channel pattern and the third channel pattern to each other,
wherein the third connection wire is disposed between the fifth connection wire and the sub-source electrode on the second channel pattern.

10. The semiconductor device of claim 9, wherein
the fifth connection wire is disposed on a same layer as the third connection wire and includes a same material as the third connection wire.

11. The semiconductor device of claim 2, further comprising
a capacitor element connected between the gate electrode and the main source electrode,
wherein the capacitor element includes:
a fourth gate electrode disposed on the barrier layer;
a first protection layer for covering the fourth gate electrode; and
a first sub-electrode disposed on the first protection layer and connected to the first connection wire.

12. The semiconductor device of claim 11, wherein
the first sub-electrode overlaps the fourth gate electrode in a thickness direction of the channel layer.

13. The semiconductor device of claim 11, further comprising
a second sub-electrode disposed on the first protection layer and connected to the sub-source electrode.

14. The semiconductor device of claim 11, wherein
the fourth gate electrode is disposed on the second connection wire.

15. The semiconductor device of claim 1, wherein
the first transistor includes:
a second channel pattern disposed on one side of the channel layer;
a first gate electrode disposed on the second channel pattern;
a first gate semiconductor layer disposed between the first gate electrode and the second channel pattern; and
a sub-source electrode and a first connection wire disposed on the second channel pattern and respectively disposed on opposite sides of the first gate electrode, and
the sub-source electrode is connected to the main source electrode, and the first connection wire is connected to the gate electrode.

16. The semiconductor device of claim 15, wherein
the barrier layer is disposed on the second channel pattern,
the second channel pattern is disposed on a same layer as the channel layer,
the first gate electrode is disposed on a same layer as the gate electrode, and
the sub-source electrode is disposed on a same layer as the main source electrode.

17. A semiconductor device comprising:
a high electron mobility transistor;
a resisting element; and
a first transistor,
wherein the high electron mobility transistor includes:
a channel layer;
a barrier layer disposed on the channel layer;
a gate electrode disposed on the barrier layer;
a gate semiconductor layer disposed between the barrier layer and the gate electrode; and
a main source electrode and a main drain electrode respectively disposed on opposite sides of the gate electrode and connected to the channel layer;
the resisting element includes:
a first channel pattern including a drift resistance region having two-dimensional electron gas;
a sub-source electrode disposed on the first channel pattern and connected to the main source electrode;
a first connection wire disposed on the first channel pattern and connected to the gate electrode; and
a second connection wire disposed between the sub-source electrode and the first connection wire and disposed on the first channel pattern, and
the first transistor includes:
a second channel pattern connected to the sub-source electrode and the first connection wire;
a first gate electrode disposed between the sub-source electrode and the first connection wire and disposed on the second channel pattern; and
a first gate semiconductor layer disposed between the first gate electrode and the second channel pattern.

18. The semiconductor device of claim 17, wherein
the semiconductor device includes:
a first inverter circuit connected to the second connection wire; and
a second inverter circuit connecting the first inverter circuit and the first gate electrode to each other.

19. The semiconductor device of claim 17, wherein
the second channel pattern is disposed between the first channel pattern and the channel layer.

20. A semiconductor device comprising:
a high electron mobility transistor;
a resisting element;
a first transistor; and
an inverter circuit,
wherein the high electron mobility transistor includes:
a channel layer;
a barrier layer disposed on the channel layer;
a gate electrode disposed on the barrier layer;
a gate semiconductor layer disposed between the barrier layer and the gate electrode; and
a main source electrode and a main drain electrode respectively disposed on opposite sides of the gate electrode and connected to the channel layer, the resisting element includes:
a first channel pattern disposed on one side of the channel layer;
a sub-source electrode disposed on the first channel pattern and connected to the main source electrode;
a first connection wire disposed on the first channel pattern and connected to the gate electrode; and
a second connection wire disposed between the sub-source electrode and the first connection wire and disposed on the first channel pattern,
the first transistor includes:
a second channel pattern disposed between the first channel pattern and the channel layer and connected to the sub-source electrode and the first connection wire;
a first gate electrode disposed between the sub-source electrode and the first connection wire and disposed on the second channel pattern; and
a first gate semiconductor layer disposed between the first gate electrode and the second channel pattern, and
the inverter circuit includes:
a third channel pattern disposed between the first channel pattern and the second channel pattern and connected to the sub-source electrode;
a third connection wire disposed on the third channel pattern and connected to 10 the first gate electrode;
a second gate electrode disposed on the third channel pattern and connected to the second connection wire; and
a second gate semiconductor layer disposed between the third channel pattern and the second gate electrode.
